(19) United States
(12) Patent Application Publication
(10) Pub. No.: US 2026/0164916 A1
(43) Pub. Date: Jun. 11, 2026

(54) PHOTOELECTRIC CONVERSION DEVICE

(71) Applicant: SONY SEMICONDUCTOR SOLUTIONS CORPORATION, KANAGAWA (JP)

(72) Inventor: KOMOMO KODAMA, KANAGAWA (JP)

(21) Appl. No.: 18/705,613

(22) PCT Filed: Sep. 12, 2022
(86) PCT No.: PCT/JP2022/034123

§ 371 Date: Apr. 29, 2024

(30) Foreign Application Priority Data
Nov. 5, 2021 (JP) 2021-181455

(51) Int. Cl. H10K 39/32

(52) U.S. Cl. CPC H10K 39/32

(57) ABSTRACT

A photoelectric conversion device according to an embodiment of the present disclosure includes a first tier, a second tier, and a plurality of first through-electrodes. The first tier includes a first first photoelectric conversion section that converts incident light into electric charge. The second tier is provided to overlap with the first tier in a first direction, and includes a first second photoelectric conversion section and a first insulating section. The first second photoelectric conversion section converts light transmitted through the first first photoelectric conversion section into electric charge. The first insulating section includes a first wall surface that surrounds the first second photoelectric conversion section along a plane orthogonal to the first direction. The plurality of first through-electrodes is each coupled to the first first photoelectric conversion section, and penetrates the second tier in a region outside the first wall surface.

### TECHNICAL FIELD

The present disclosure relates to a photoelectric conversion device.

### Background Art

There has been proposed an imaging element including a through-electrode that transmits a signal corresponding to electric charge photoelectrically converted by an organic photoelectric conversion film, with an insulating film being formed between the through-electrode and a photodiode to coat the through-electrode (PTL 1).

### CITATION LIST

### Patent Literature

PTL 1: International Publication No. WO 2016/143531

### SUMMARY OF THE INVENTION

It is desired for a device that photoelectrically converts light to have improved charge transfer characteristics.

It is desirable to provide a photoelectric conversion device that makes it possible to improve charge transfer characteristics.

A photoelectric conversion device according to an embodiment of the present disclosure includes a first tier, a second tier, and a plurality of first through-electrodes. The first tier includes a first first photoelectric conversion section that converts incident light into electric charge. The second tier is provided to overlap with the first tier in a first direction, and includes a first second photoelectric conversion section and a first insulating section. The first second photoelectric conversion section converts light transmitted through the first first photoelectric conversion section into electric charge. The first insulating section includes a first wall surface that surrounds the first second photoelectric conversion section along a plane orthogonal to the first direction. The plurality of first through-electrodes is each coupled to the first first photoelectric conversion section, and penetrates the second tier in a region outside the first wall surface.

### BRIEF DESCRIPTION OF THE DRAWINGS

FIG. 1 is a block diagram illustrating an example of an overall configuration of an imaging device according to an embodiment of the present disclosure.

FIG. 2 is a diagram illustrating an example of a planar configuration of the imaging device according to an embodiment of the present disclosure.

FIG. 3 is a diagram illustrating an example of a planar configuration of pixels of the imaging device according to an embodiment of the present disclosure.

FIG. 4 is a diagram illustrating an example of a cross-sectional configuration of pixels of the imaging device according to an embodiment of the present disclosure.

FIG. 5 is a diagram illustrating another example of the cross-sectional configuration of the pixels of the imaging device according to an embodiment of the present disclosure.

FIG. 6 is a diagram illustrating an example of a planar configuration of pixels of an imaging device according to Modification Example 1.

FIG. 7 is a diagram illustrating another example of the planar configuration of the pixels of the imaging device according to Modification Example 1.

FIG. 8 is a diagram illustrating another example of the planar configuration of the pixels of the imaging device according to Modification Example 1.

FIG. 9 is a diagram illustrating another example of the planar configuration of the pixel of the imaging device according to Modification Example 1.

FIG. 10 is a diagram illustrating an example of a planar configuration of a pixel of an imaging device according to Modification Example 2.

FIG. 11 is a diagram illustrating another example of the planar configuration of the pixel of the imaging device according to Modification Example 2.

FIG. 12 is a diagram illustrating another example of the planar configuration of the pixels of the imaging device according to Modification Example 2.

FIG. 13 is a diagram illustrating another example of the planar configuration of the pixels of the imaging device according to Modification Example 2.

FIG. 14 is a diagram illustrating an example of a cross-sectional configuration of pixels of an imaging device according to Modification Example 3.

FIG. 15 is a diagram illustrating another example of the cross-sectional configuration of the pixels of the imaging device according to Modification Example 3.

FIG. 16 is a diagram illustrating an example of a planar configuration of a pixel of an imaging device according to Modification Example 4.

FIG. 17 is a diagram illustrating another example of the planar configuration of the pixel of the imaging device according to Modification Example 4.

FIG. 18 is a diagram illustrating another example of the planar configuration of the pixel of the imaging device according to Modification Example 4.

FIG. 19 is a diagram illustrating another example of the planar configuration of the pixel of the imaging device according to Modification Example 4.

FIG. 20 is a diagram illustrating another example of the planar configuration of the pixel of the imaging device according to Modification Example 4.

FIG. 21 is a diagram illustrating an example of a cross-sectional configuration of pixels of an imaging device according to Modification Example 5.

FIG. 22 is a diagram illustrating an example of a cross-sectional configuration of pixels of an imaging device according to Modification Example 6.

FIG. 23 is a diagram illustrating an example of a cross-sectional configuration of pixels of an imaging device according to Modification Example 7.

FIG. 24 is a diagram illustrating another example of the cross-sectional configuration of the pixels of the imaging device according to Modification Example 7.

FIG. 25 is a diagram illustrating an example of a cross-sectional configuration of pixels of an imaging device according to Modification Example 8.

FIG. 26 is a diagram illustrating another example of the cross-sectional configuration of the pixels of the imaging device according to Modification Example 8.

FIG. 27 is a diagram illustrating an example of a planar configuration of pixels of an imaging device according to Modification Example 9.

FIG. 28 is a diagram illustrating an example of a cross-sectional configuration of the pixels of the imaging device according to Modification Example 9.

FIG. 29 is a diagram illustrating an example of a cross-sectional configuration of the pixels of the imaging device according to Modification Example 9.

FIG. 30 is a diagram illustrating another example of the cross-sectional configuration of the pixels of the imaging device according to Modification Example 9.

FIG. 31 is a diagram illustrating another example of the cross-sectional configuration of the pixels of the imaging device according to Modification Example 9.

FIG. 32 is a diagram illustrating an example of a planar configuration of pixels of an imaging device according to Modification Example 10.

FIG. 33 is a diagram illustrating an example of a cross-sectional configuration of the pixels of the imaging device according to Modification Example 10.

FIG. 34 is a diagram illustrating an example of a cross-sectional configuration of the pixels of the imaging device according to Modification Example 10.

FIG. 35 is a diagram illustrating an example of a cross-sectional configuration of the pixels of the imaging device according to Modification Example 10.

FIG. 36 is a block diagram illustrating a configuration example of an electronic apparatus including the imaging device.

FIG. 37 is a block diagram depicting an example of schematic configuration of a vehicle control system.

FIG. 38 is a diagram of assistance in explaining an example of installation positions of an outside-vehicle information detecting section and an imaging section.

FIG. 39 is a view depicting an example of a schematic configuration of an endoscopic surgery system.

FIG. 40 is a block diagram depicting an example of a functional configuration of a camera head and a camera control unit (CCU).

### MODES FOR CARRYING OUT THE INVENTION

Hereinafter, description is given in detail of embodiments of the present disclosure with reference to the drawings. It is to be noted that the description is given in the following order.
1. Embodiment
2. Modification Examples
3. Application Example
4. Practical Application Examples

### 1. Embodiment

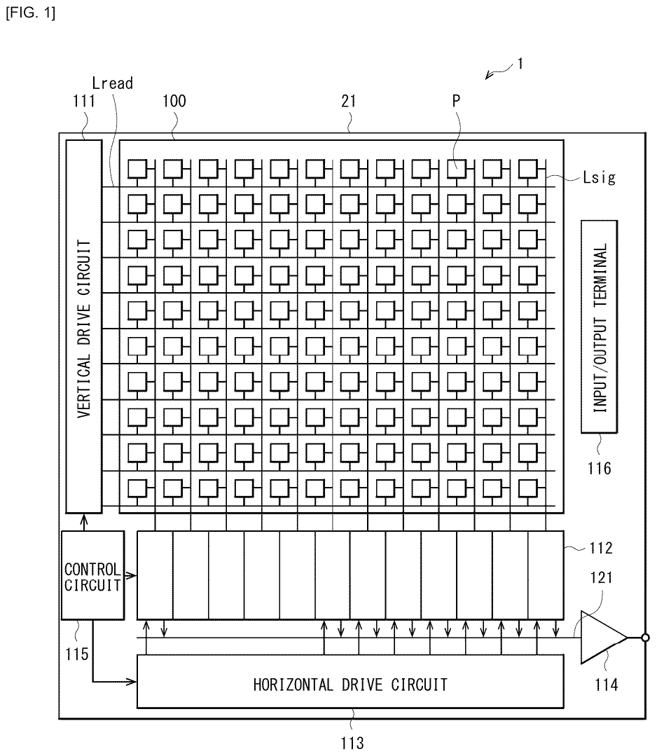

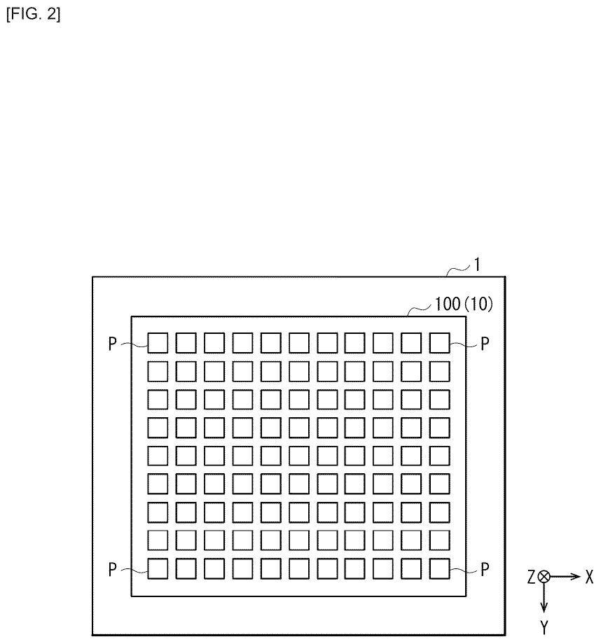

FIG. 1 is a block diagram illustrating an example of an overall configuration of an imaging device 1, which is an example of a photoelectric conversion device according to an embodiment of the present disclosure. FIG. 2 is a diagram illustrating an example of a planar configuration of the imaging device 1. The imaging device 1 as the photoelectric conversion device is a device that photoelectrically converts incident light, and captures an image of a subject. The imaging device 1 is, for example, a CMOS (Complementary Metal Oxide Semiconductor) image sensor.

In the imaging device 1, pixels P each including a photoelectric conversion section are arranged in matrix. As illustrated in FIG. 2, the imaging device 1 includes, as an imaging area, a region (a pixel section 100) in which a plurality of pixels P is two-dimensionally arranged in matrix. The imaging device 1 can be utilized for an electronic apparatus such as a digital still camera or a video camera. It is to be noted that, as illustrated in FIG. 2, a direction of incidence of light from a subject is defined as a Z-axis direction, a horizontal direction on the sheet orthogonal to the Z-axis direction is defined as an X-axis direction, and a vertical direction on the sheet orthogonal to the Z axis and the X axis is defined as a Y-axis direction. In the subsequent figures, a direction may be expressed with reference to the directions of arrows in FIG. 2 in some cases.

### [Schematic Configuration of Imaging Device]

The imaging device 1 takes in incident light (image light) from a subject via an optical lens system (unillustrated). The imaging device 1 converts the amount of incident light formed as an image on an imaging surface into electric signals on a pixel-by-pixel basis, and outputs the electric signals as pixel signals. The imaging device 1 includes the pixel section 100 as the imaging area. In addition, the imaging device 1 includes, in a peripheral region of the pixel section 100, for example, a vertical drive circuit 111, column signal processing circuits 112, a horizontal drive circuit 113, an output circuit 114, a control circuit 115, and an input/output terminal 116.

In the pixel section 100, the plurality of pixels P is two-dimensionally arranged in matrix. The pixel section 100 is provided with a plurality of pixel rows configured by the plurality of pixels P arranged in a horizontal direction (a transverse direction on the sheet) and with a plurality of pixel columns configured by the plurality of pixels P arranged in a vertical direction (a longitudinal direction on the sheet).

For example, a pixel drive line Lread (a row selection line and a reset control line) is wired to the pixel section 100 for each of pixel rows, and a vertical signal line Lsig is wired to the pixel section 100 for each of pixel columns. The pixel drive line Lread transmits drive signals for reading signals from the pixels. One end of the pixel drive line Lread is coupled to an output end of the vertical drive circuit 111 corresponding to each of the rows.

The vertical drive circuit 111 is configured by a shift register, an address decoder, and the like. The vertical drive circuit 111 is a pixel drive section that drives the pixels P of the pixel section 100A on a row-by-row basis, for example. The column signal processing circuits 112 are each configured by an amplifier, a horizontal selection switch, and the like provided for each of the vertical signal lines Lsig. Signals outputted from the respective pixels P in the pixel rows selectively scanned by the vertical drive circuit 111 are supplied to the column signal processing circuits 112 through the vertical signal lines Lsig.

The horizontal drive circuit 113 is configured by a shift register, an address decoder, and the like. The horizontal drive circuit 113 drives respective horizontal selection switches of the column signal processing circuits 112 in order while scanning the horizontal selection switches. The selective scanning by this horizontal drive circuit 113 causes signals of the respective pixels transmitted through the respective vertical signal lines Lsig to be outputted to a horizontal signal line 121 in order and causes the signals to be transmitted to the outside of a semiconductor substrate 21 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuits 112, the horizontal drive circuit 113, the horizontal signal line 121, and the output circuit 114 may be formed in the semiconductor substrate 21, or may be provided on an external control IC. In addition, the circuit portion may be formed in another substrate coupled by a cable or the like.

The control circuit 115 receives a clock supplied from the outside of the semiconductor substrate 21, data for an instruction about an operation mode, and the like, and also outputs data such as internal information on the imaging device 1. The control circuit 115 further includes a timing generator that generates various timing signals, and controls driving of the peripheral circuits including the vertical drive circuit 111, the column signal processing circuits 112, the horizontal drive circuit 113, and the like on the basis of the various timing signals generated by the timing generator. The input/output terminal 116 exchanges signals with the outside.

### [Configuration of Pixel]

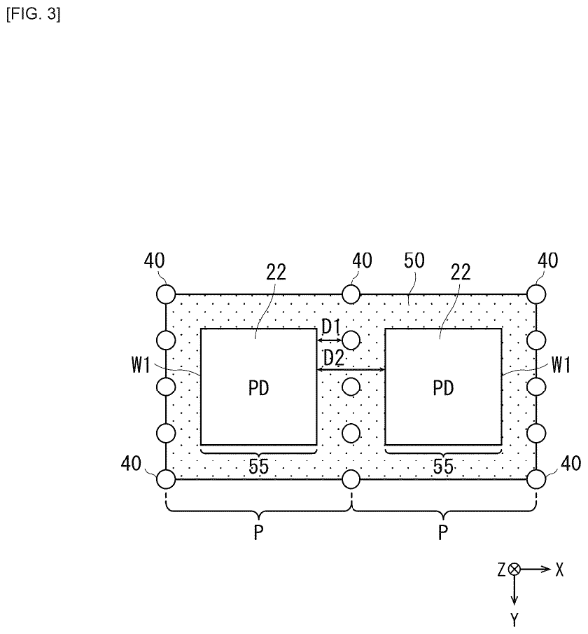

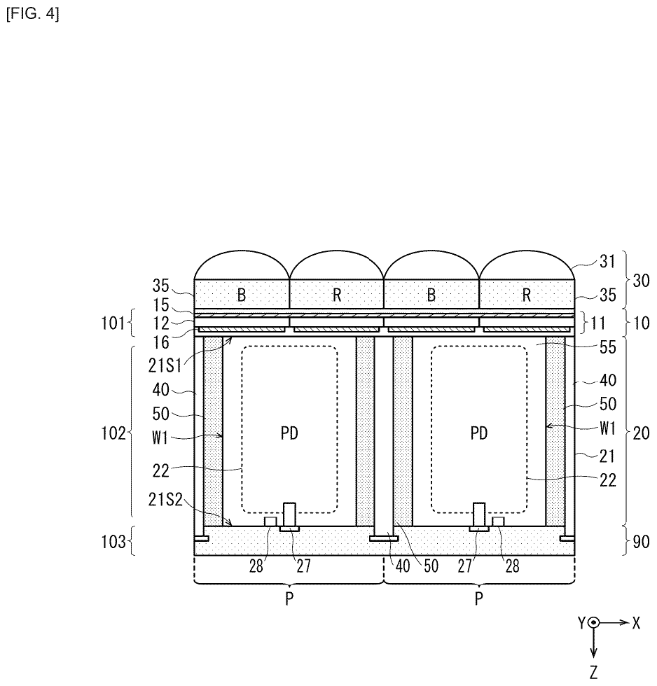

FIG. 3 is a diagram illustrating an example of a planar configuration of pixels of the imaging device 1 according to the embodiment. FIG. 4 is a diagram illustrating an example of a cross-sectional configuration of the pixels of the imaging device 1 according to the embodiment. The pixel P of the imaging device 1 includes a first photoelectric conversion section 11, a second photoelectric conversion section 22, a through-electrode 40, and an insulating section 50. The first photoelectric conversion section 11 is configured using an organic material. The first photoelectric conversion section 11 converts incident light into electric charge, and accumulates the photoelectrically converted electric charge.

The second photoelectric conversion section 22 is configured by, for example, a photodiode (PD), and converts incident light into electric charge. In the present embodiment, the second photoelectric conversion section 22 photoelectrically converts light transmitted through the first photoelectric conversion section 11, and accumulates the photoelectrically converted electric charge. A plurality of and the insulating section 50 are provided around the second photoelectric conversion section 22. The through-electrode 40 is a coupling section, and couples circuits to each other provided in different layers.

The imaging device 1 is provided with more than one through-electrode 40 per pixel. In the imaging device 1, for example, the plurality of through-electrodes 40 is formed for each second photoelectric conversion section 22. In the example illustrated in FIG. 3, the through-electrode 40 is positioned at a boundary between the pixels P adjacent to each other. The through-electrodes 40 are arranged side by side at an interval narrower than a pixel pitch (pixel interval) at a boundary part between the pixels P adjacent to each other. For example, the through-electrodes 40 are arranged on the left and on the right of the second photoelectric conversion section 22. In the example illustrated in FIG. 3, the through-electrodes 40 are arranged side by side in the Y-axis direction at the boundary part between the pixels P adjacent to each other.

The insulating section 50 is provided between the through-electrodes 40 adjacent to each other and between the through-electrode 40 and the second photoelectric conversion section 22. The insulating section 50 may also be referred to as a separation section that separates the pixels P from each other. The plurality of through-electrodes 40 and the second photoelectric conversion section 22 are electrically insulated from each other by the insulating section 50. In the example illustrated in FIG. 3, the insulating section 50 is provided to surround each of the second photoelectric conversion section 22 and the through-electrode 40. The circumference of the through-electrode 40 is covered with the insulating section 50. It can also be said that the insulating section 50 has an opening 55 in which the second photoelectric conversion section 22 is positioned, as illustrated in FIG. 3.

As illustrated in FIG. 4, the imaging device 1 has a configuration, for example, in which a first light-receiving unit 10, a second light-receiving unit 20, a light-guiding unit 30, and a multilayer wiring layer 90 are stacked in the Z-axis direction. As described above, the pixel P includes the first photoelectric conversion section 11 and the second photoelectric conversion section 22. As in the example illustrated in FIG. 4, the pixel P has a structure in which the first photoelectric conversion section 11 and the second photoelectric conversion section 22 are stacked.

The first light-receiving unit 10 is provided in a first tier 101 of a plurality of stacked tiers. In addition, the second light-receiving unit 20 is provided in a second tier 102. A wiring layer of the multilayer wiring layer 90 has a wiring line coupled to the through-electrode 40, and is provided in a third tier 103. The first tier 101 including the first photoelectric conversion section 11 is provided to overlap with the second tier 102 including the second photoelectric conversion section 22.

The first light-receiving unit 10 includes a plurality of first photoelectric conversion sections 11. The first photoelectric conversion section 11 includes a photoelectric conversion film 12, a first electrode 15, and a second electrode 16. The photoelectric conversion film 12 is configured by an organic material, and converts incident light into electric charge. The imaging device 1 is provided with a plurality of photoelectric conversion films 12 formed by an organic semiconductor material for each of the pixels P, for example.

The first electrode 15 and the second electrode 16 are each a transparent electrode, and configured by, for example, ITO (indium tin oxide). The first electrode 15 and the second electrode 16 may be configured by a tin oxide-based material, a zinc oxide-based material, or the like. The first electrode 15 and the second electrode 16 may be formed by another transparent electrically-conductive material.

As illustrated in FIG. 4, the first electrode 15 is an electrode common to the photoelectric conversion films 12 of the plurality of pixels P, and is provided on a side of one surface of the photoelectric conversion film 12. The second electrode 16 is provided on a side of the other surface of the photoelectric conversion film 12 for each of the photoelectric conversion films 12. The first electrode 15 and the second electrode 16 are disposed with the photoelectric conversion film 12 interposed therebetween.

The first electrode 15 is an upper electrode of the photoelectric conversion film 12, and the second electrode 16 is a lower electrode of the photoelectric conversion film 12. The first electrode 15 and the second electrode 16 are each coupled to circuits provided in the multilayer wiring layer 90 and the semiconductor substrate 21 via the through-electrodes 40 different from each other.

The second light-receiving unit 20 includes the semiconductor substrate 21 having a first surface 21S1 and a second surface 21S2 opposed to each other. The light-guiding unit 30 and the first light-receiving unit 10 are provided on a side of the first surface 21S1 of the semiconductor substrate 21, and the multilayer wiring layer 90 is provided on a side of the second surface 21S2 of the semiconductor substrate 21. It can also be said that the light-guiding unit 30 and the first light-receiving unit 10 are provided on a side on which light from the optical lens system is incident and that the multilayer wiring layer 90 is provided on a side opposite to the light incident side. The imaging device 1 is a so-called back side illumination imaging device.

The semiconductor substrate 21 is configured by, for example, a silicon substrate. The second photoelectric conversion section 22 is a photodiode (PD), and has a p-n junction in a predetermined region of the semiconductor substrate 21. A plurality of second photoelectric conversion sections 22 is formed to be embedded in the semiconductor substrate 21. In the second light-receiving unit 20, the plurality of second photoelectric conversion sections 22 is provided along the first surface 21S1 and the second surface 21S2 of the semiconductor substrate 21.

The multilayer wiring layer 90 has a configuration, for example, in which wiring layers are stacked with an interlayer insulating layer interposed therebetween. The wiring layer of the multilayer wiring layer 90 is formed using, for example, aluminum (Al), copper (Cu), tungsten (W), or the like. In addition thereto, the wiring layer may be formed using polysilicon (Poly-Si). The interlayer insulating layer is formed by, for example, a monolayer film including one of silicon oxide (SiOₓ), TEOS, silicon nitride (SiNₓ), or silicon oxynitride (SiOₓN_{y}), or a stacked film including two or more thereof.

There is formed, in the semiconductor substrate 21 and the multilayer wiring layer 90, a circuit (e.g., a transfer transistor, a reset transistor, an amplification transistor, etc.) to read a pixel signal based on electric charge generated by the first photoelectric conversion section 11 and a pixel signal based on electric charge generated by the second photoelectric conversion section 22. In addition, for example, the vertical drive circuit 111, the column signal processing circuits 112, the horizontal drive circuit 113, the output circuit 114, the control circuit 115, the input/output terminal 116, and the like, which are described above, are formed in the semiconductor substrate 21 and the multilayer wiring layer 90.

The pixel P includes a first readout circuit that reads a pixel signal based on electric charge photoelectrically converted by the first photoelectric conversion section 11. The first readout circuit includes a floating diffusion (FD), a reset transistor, an amplification transistor, and the like. Electric charge photoelectrically converted by the first photoelectric conversion section 11 and accumulated is transferred by the first electrode 15 and the second electrode 16 to the FD of the first readout circuit via the through-electrode 40. The FD is a charge accumulation section, and accumulates the transferred electric charge.

The amplification transistor of the first readout circuit outputs a pixel signal based on electric charge accumulated in the FD. The first readout circuit is able to read the pixel signal based on the electric charge converted by the first photoelectric conversion section 11 to the vertical signal line Lsig. The reset transistor may reset the electric charge accumulated in the FD and may reset a voltage of the FD.

In addition, the pixel P includes a second readout circuit that reads a pixel signal based on electric charge photoelectrically converted by the second photoelectric conversion section 22. The second readout circuit includes a transfer transistor, a floating diffusion (FD) 28, a reset transistor, an amplification transistor, and the like. The transfer transistor of the second readout circuit is a transfer section, and transfers electric charge photoelectrically converted by the second photoelectric conversion section 22 and accumulated to the FD 28. A gate electrode 27 of the transfer transistor is an electrode to read the electric charge generated by the second photoelectric conversion section 22. As illustrated in FIG. 4, for example, the gate electrode 27 is provided at a middle part of the second photoelectric conversion section 22 on the second surface 21S2. The FD 28 is a charge accumulation section, and accumulates the transferred electric charge.

The amplification transistor of the second readout circuit outputs a pixel signal based on the electric charge accumulated in the FD 28. The second readout circuit is able to read the pixel signal based on the electric charge converted by the second photoelectric conversion section 22 to the vertical signal line Lsig. The reset transistor of the second readout circuit may reset the electric charge accumulated in the FD 28, and may reset a voltage of the FD 28. It is to be noted that FIG. 4 illustrates the gate electrode 27 and the FD 28 of the transfer transistor.

The light-guiding unit 30 includes a lens section 31 that condenses light, and a color filter 35. The light-guiding unit 30 is stacked on the first light-receiving unit 10, and guides light incident from above in FIG. 4 to a side of the first light-receiving unit 10. The lens section 31 is an optical member also referred to as an on-chip lens.

The color filter 35 selectively transmits light of a specific wavelength region of incident light. For the first photoelectric conversion section 11 of the imaging device 1, for example, the color filter 35 that transmits red (R) light, the color filter 35 that transmits green (G) light, the color filter 35 that transmits blue (B) light, and the like are provided. In the example illustrated in FIG. 4, the color filter 35 that transmits blue (B) light is provided on the first photoelectric conversion section 11 on the left side of the left and right first photoelectric conversion sections 11 in the pixel P. The first photoelectric conversion section 11 on the left side receives blue wavelength light to perform photoelectric conversion.

The color filter 35 that transmits red (R) light is provided on the first photoelectric conversion section 11 on the right side of the left and right first photoelectric conversion sections 11 in the pixel P. The first photoelectric conversion section 11 on the right side receives red wavelength light to perform photoelectric conversion. It is to be noted that the first photoelectric conversion section 11 disposed below the color filter 35 that transmits green (G) light receives green wavelength light to perform photoelectric conversion. This enables the respective pixels P of the imaging device 1 to generate an R component pixel signal, a G component pixel signal, and a B component pixel signal. It is thus possible for the imaging device 1 to obtain RGB pixel signals.

It is to be noted that the color filter 35 is not limited to a color filter of a primary color system (RGB) but may be a color filter of a complementary color system such as Cy (cyan), Mg (magenta), or Ye (yellow). In addition, a color filter corresponding to W (white), i.e., a filter that transmits light of all wavelength regions of incident light may be disposed. It is to be noted that, in a case where the first photoelectric conversion section 11 that selectively and photoelectrically converts light of a specific wavelength region is disposed, the color filter 35 may not be disposed for this first photoelectric conversion section 11. In addition, a filter may be disposed between the first photoelectric conversion section 11 and the second photoelectric conversion section 22. For example, the color filter as described above or a filter (IR pass filter) that transmits infrared light may be disposed between the first photoelectric conversion section 11 and the second photoelectric conversion section 22.

Light having passed through the first photoelectric conversion section 11 is incident on the second photoelectric conversion section 22 of the pixel P. In the example illustrated in FIG. 4, light transmitted through the lens section 31, the color filter 35, and the first photoelectric conversion section 11 is incident on the second photoelectric conversion section 22. The second photoelectric conversion section 22 photoelectrically converts light transmitted through the first photoelectric conversion section 11 to generate electric charge. It is possible for the imaging device 1 to obtain a pixel signal based on electric charge converted by the first photoelectric conversion section 11 and a pixel signal based on electric charge converted by the second photoelectric conversion section 22.

The second photoelectric conversion section 22 is utilized for distance measurement of a TOF (Time Of Flight) method, as an example. In the imaging device 1, a subject is irradiated with light (e.g., infrared light), and the light reflected from the subject is received by the second photoelectric conversion section 22. For example, the second photoelectric conversion section 22 receives infrared light reflected by the subject and transmitted through the first photoelectric conversion section 11, and generates electric charge by photoelectric conversion.

The pixel P generates a pixel signal corresponding to electric charge converted by the second photoelectric conversion section 22. This pixel signal is a signal corresponding to a distance to a subject as a measurement target, and can also be said to be distance information on the object. The imaging device 1 presumes a phase difference between irradiation light and reflected light, i.e., round-trip time of light on the basis of the generated pixel signal to calculate a distance between the imaging device 1 and the subject. The distance to the measurement object is calculated by arithmetic operation on the basis of time during which light irradiated from a light source is reflected by the measurement object to reach the imaging device 1. It is thus possible for the imaging device 1 to detect the distance information for each of the pixels P.

In this manner, it is possible for the imaging device 1 according to the present embodiment to generate a visible image using the RGB pixel signals obtained by photoelectric conversion by the first photoelectric conversion section 11. In addition, it is possible for the imaging device 1 to generate a distance image, which is an image indicating the distance to the subject, using the pixel signal obtained by photoelectric conversion by the second photoelectric conversion section 22.

It is to be noted that the second photoelectric conversion section 22 is also able to generate electric charge by photoelectrically converting visible light transmitted through the first photoelectric conversion section 11. The second photoelectric conversion section 22 may be utilized to generate the visible image. In addition, the second photoelectric conversion section 22 may be utilized for an event-driven sensor (referred to as EVS (Event Vision Sensor), EDS (Event Driven Sensor), DVS (Dynamic Vision Sensor), etc.), an SPAD (Single Photon Avalanche Diode) sensor, or the like.

The through-electrode 40 provided in the imaging device 1 is an electrode that penetrates the semiconductor substrate 21 of the second light-receiving unit 20. As illustrated in FIG. 4, the through-electrode 40 extends in the Z-axis direction, and is formed to reach the multilayer wiring layer 90. The through-electrode 40 penetrates the second tier 102 around the second photoelectric conversion section 22. It can also be said that the through-electrode 40 is provided to penetrate the insulating section 50. The through-electrode 40 is able to electrically couple an element provided on the side of the first surface 21S1 of the semiconductor substrate 21 and an element provided on the side of the second surface 21S2 of the semiconductor substrate 21 to each other.

The through-electrode 40 is configured by, for example, PDAS (Phosphorus Doped Amorphous Silicon), polysilicon (Poly-Si), or the like. It is to be noted that the through-electrode 40 may also be formed by a metal material such as aluminum (Al), tungsten (W), titanium (Ti), cobalt (Co), hafnium (Hf), or tantalum (Ta).

The first photoelectric conversion section 11 of the first light-receiving unit 10 is electrically coupled to circuits of the multilayer wiring layer 90 and the semiconductor substrate 21 via the through-electrode 40. The plurality of through-electrodes 40 arranged for each of the pixels P includes the through-electrode 40 that transfers electric charge converted by the first photoelectric conversion section 11 of the pixel P, the through-electrode 40 that transmits a signal to control the first photoelectric conversion section 11, or the like.

The first electrode 15 and the second electrode 16 of the first photoelectric conversion section 11 are each coupled to a circuit provided in the semiconductor substrate 21 via the mutually different through-electrodes 40. The first electrode 15 of the first photoelectric conversion section 11 is electrically coupled to a circuit that controls the first photoelectric conversion section 11 via the through-electrode 40 coupled to the first electrode 15. The first electrode 15 is electrically coupled to the vertical drive circuit 111 provided in the semiconductor substrate 21 via the through-electrode 40, for example. It becomes possible for the vertical drive circuit 111 to supply the first electrode 15 with a voltage that drives the first photoelectric conversion section 11 via the through-electrode 40.

The second electrode 16 of the first photoelectric conversion section 11 is electrically coupled to a gate electrode of the amplification transistor and the FD of the first readout circuit provided in the semiconductor substrate 21, for example, via the through-electrode 40 coupled to the second electrode 16. The vertical drive circuit 111 provides a predetermined potential to the first electrode 15, enabling the second electrode 16 to transfer electric charge converted by the photoelectric conversion film 12 to the first readout circuit. The through-electrode 40 electrically coupled to the second electrode 16 transmits signal charge generated by the photoelectric conversion film 12 to the first readout circuit. It becomes possible for the first readout circuit to output a pixel signal based on electric charge converted by the first photoelectric conversion section 11.

The insulating section 50 is provided between the through-electrode 40 and the second photoelectric conversion section 22. As illustrated in FIGS. 3 and 4, the insulating section 50 is formed along the through-electrode 40 to coat the circumference of the through-electrode 40. The insulating section 50 has a wall surface W1 surrounding the second photoelectric conversion section 22, along a plane orthogonal to a stacking direction of the first tier 101 provided with the first photoelectric conversion section 11 and the second tier 102 provided with the second photoelectric conversion section 22.

In the imaging device 1, the plurality of through-electrodes 40 each electrically coupled to the first photoelectric conversion section 11 penetrates the second tier 102 in a region outside the wall surface W1 of the insulating section 50. In addition, in the present embodiment, the wall surface W1 of the insulating section 50 has a planar shape, as illustrated in FIGS. 3 and 4. As in the example illustrated in FIG. 3, in an X-Y plane, an angle formed by tangents of any two points on the wall surface W1 does not exceed 180°. The insulating section 50 is configured by, for example, silicon oxide (SiOₓ), TEOS, silicon nitride (SiNₓ), silicon oxynitride (SiOₓN_{y}), or the like. It is to be noted that the insulating section 50 may be formed using another dielectric material having an insulation property.

The insulating section 50 has the opening 55 defined by the wall surface W1. As illustrated in FIG. 3, an end of the opening 55 is distant from the region where the through-electrodes 40 are arranged. The opening 55 has a planar shape on a side of the through-electrode 40. In the example illustrated in FIG. 3, the opening 55 has a quadrangular shape, with four sides being surrounded by the wall surface W1 having a flat shape. In the X-Y plane, the end of the opening 55 has a planar shape. It can also be said that the insulating section 50 has a planar part at a location of the side of the opening 55.

The opening 55 is provided for each of the pixels P arranged in the imaging device 1. As illustrated in FIG. 3, an interval (distance) D2 between the opening 55 of a certain pixel and the opening 55 of a pixel next to this pixel is greater than an interval D1 between the opening 55 and the through-electrode 40. In addition, in the X-Y plane, the interval between the openings 55 adjacent to each other is wider than a diameter of the through-electrode 40.

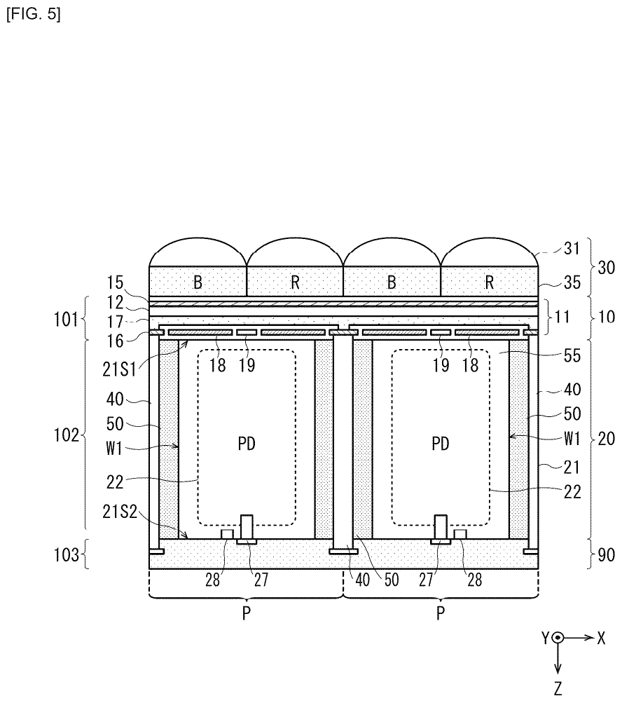

It is to be noted that, as in the example illustrated in FIG. 5, the first photoelectric conversion section 11 of the imaging device 1 may include an accumulation section 17 that accumulates the electric charge converted by the photoelectric conversion film 12. For example, the accumulation section 17 configured using an inorganic semiconductor material may be disposed to face the photoelectric conversion film 12, as illustrated in FIG. 5. In the example illustrated in FIG. 5, the first photoelectric conversion section 11 includes a third electrode 18 and a fourth electrode 19. The fourth electrode 19 is a shield electrode, and causes a potential barrier to separate the pixels P from each other, in the accumulation section 17. The first electrode 15 and the third electrode 18 are disposed with the photoelectric conversion film 12 and the accumulation section 17 interposed therebetween. In the example illustrated in FIG. 5, electric charge generated by the photoelectric conversion film 12 can be accumulated in a region part of the accumulation section 17 facing the third electrode 18, depending on a potential difference between the first electrode 15 and the third electrode 18. It is to be noted that the third electrode 18 and the fourth electrode 19 are transparent electrodes in the same manner as the first electrode 15 and the second electrode 16, and are each configured by ITO, or the like.

### [Workings and Effects]

The photoelectric conversion device (imaging device 1) according to the present embodiment includes: the first tier 101, the second tier 102 provided to be stacked on the first tier 101 in a first direction, and a plurality of first through-electrodes (through-electrodes 40). The first tier 101 includes a first first photoelectric conversion section 11 that converts incident light into electric charge. The second tier 102 includes a first second photoelectric conversion section 22 that converts light transmitted through the first first photoelectric conversion section 11 into electric charge, and a first insulating section (insulating section 50) including a first wall surface (wall surface W1) that surrounds the first second photoelectric conversion section 22 along a plane orthogonal to the first direction. The first through-electrodes (through-electrodes 40) are each coupled to the first first photoelectric conversion section 11, and penetrate the second tier 102 in a region outside the first wall surface.

In the imaging device 1 according to the present embodiment, the through-electrodes 40 are provided for each of the pixels P. The through-electrodes 40 are each provided to penetrate the second tier 102 in a region outside the wall surface W1 of the insulating section 50 that surrounds the second photoelectric conversion section 22. It is therefore possible to prevent an increase in time for charge transfer from the second photoelectric conversion section 22, and thus to improve charge transfer characteristics. It becomes possible to prevent deterioration in pixel characteristics.

If the wall surface of the insulating section provided in the imaging device 1 is not planar, there is a possibility that the transfer characteristics of electric charge photoelectrically converted by the second photoelectric conversion section 22 may be deteriorated. For example, in a case where the wall surface of the insulating section has an uneven shape, time required to transfer electric charge from a part of the second photoelectric conversion section 22 near the wall surface of the insulating section is considered to be increased. In such a case, it is not possible for the transfer transistor to efficiently transfer the electric charge photoelectrically converted by the second photoelectric conversion section 22 to the FD, which may degrade the quality of the pixel signal. In a case where the second photoelectric conversion section 22 is utilized for a TOF sensor, the accuracy of the distance to the subject calculated using the pixel signal may possibly be reduced. In particular, in a case where more than one through-electrode is arranged per pixel and an insulating section having an uneven wall surface is formed along the plurality of through-electrodes, charge transfer to the FD is significantly delayed, thus causing the distance measurement accuracy to be easily degraded.

Thus, in the imaging device 1 according to the present embodiment, the through-electrode 40 is provided to penetrate the second tier 102 in a region outside the wall surface W1 surrounding the second photoelectric conversion section 22, so as not to allow the wall surface W1 of the insulating section 50 to have an uneven shape. As described above, the insulating section 50 includes the wall surface W1 having a planar shape. In the present embodiment, it is therefore possible to avoid the increase in time required to transfer electric charge from a part of the second photoelectric conversion section 22 near the wall surface W1 of the insulating section 50. It becomes possible to reduce the time during which the electric charge converted in the region of the second photoelectric conversion section 22 near the wall surface W1 of the insulating section 50 reaches the gate electrode 27 of the transfer transistor provided at the middle part of the second photoelectric conversion section 22, and thus to improve the charge transfer characteristics.

In a case where the second photoelectric conversion section 22 is applied to the TOF sensor, it is possible to suppress a decrease in transfer efficiency of electric charge generated by the second photoelectric conversion section 22 and thus to improve the distance measurement accuracy. In addition, as compared with a case of providing an uneven insulating section along the through-electrode 40, it is possible to reduce a capacitance to be added between the second photoelectric conversion section 22 and the through-electrode 40. It becomes possible to reduce a parasitic capacitance to be added to the through-electrode 40, thus making it possible to improve signal transmission characteristics in the through-electrode 40.

Next, description is given of modification examples of the present disclosure. Hereinafter, components similar to those of the foregoing embodiment are denoted by the same reference numerals, and description thereof are omitted as appropriate.

### 2. Modification Examples

### 2-1. Modification Example 1

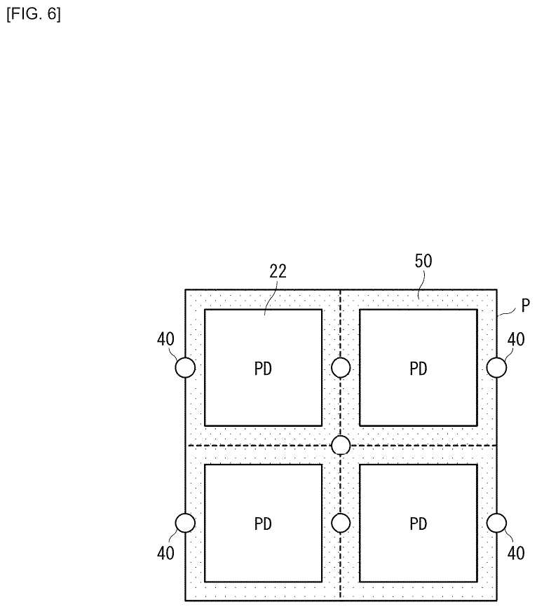

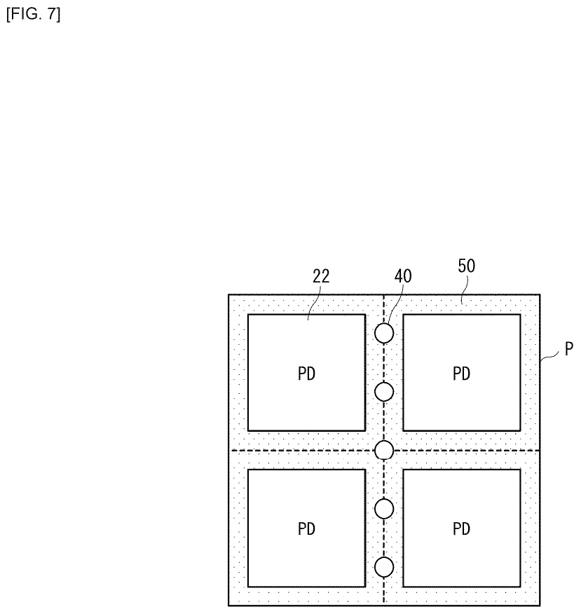

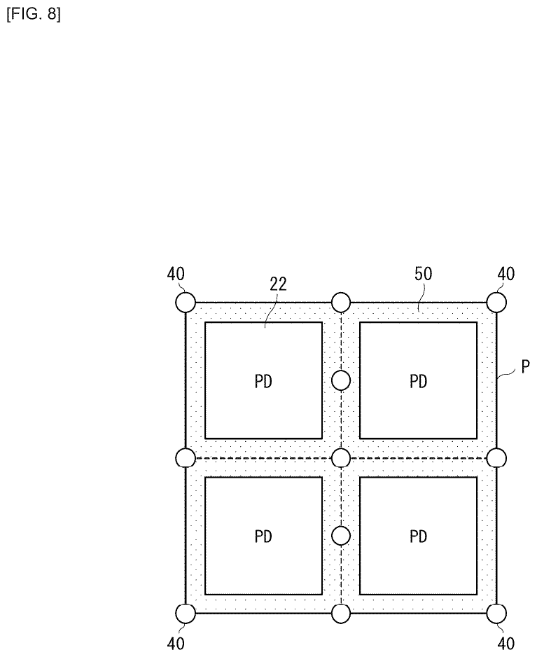

The foregoing embodiment describes the example of the arrangement of the through-electrodes 40, but the number and the arrangement of the through-electrodes 40 are not limited thereto. FIGS. 6 to 8 are diagrams each illustrating an example of a planar configuration of pixels of the imaging device 1 according to Modification Example 1. As in the example illustrated in FIG. 6, the through-electrodes 40 may be provided in a middle region at the boundary between the pixels P adjacent to each other and at a corner (angular part) of the pixel P. In addition, the through-electrodes 40 may also be arranged in a region other than the middle at the boundary between the pixels P adjacent to each other. In the example illustrated in FIG. 7, the through-electrodes 40 are arranged as a whole on a portion of the sides of the four pixels P. It is to be noted that, in each of the examples illustrated in FIGS. 6 and 7, 5/4 through-electrodes 40 are arranged per pixel. As illustrated in FIG. 8, the through-electrodes 40 may be provided in a middle region at the boundary between the pixels P adjacent to each other and at four corners of the pixel P. In the example illustrated in FIGS. 8, 6/4 through-electrodes 40 are arranged per pixel.

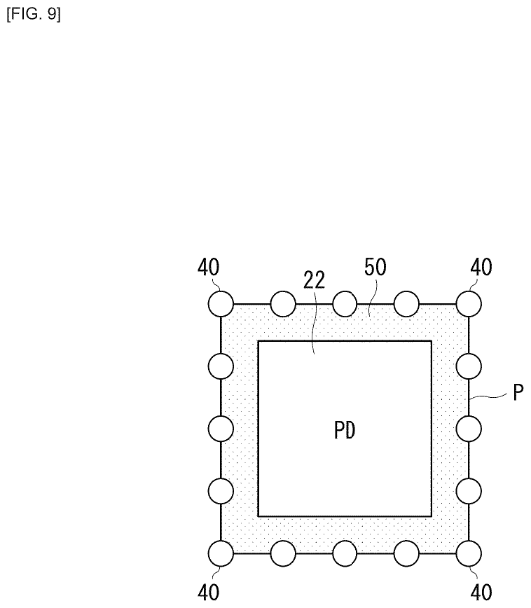

FIG. 9 is a diagram illustrating another example of the planar configuration of the pixel of the imaging device 1 according to Modification Example 1. As illustrated in FIG. 9, the plurality of through-electrodes 40 may be arranged in the horizontal direction and the vertical direction (X-axis direction and Y-axis direction). The plurality of through-electrodes 40 is provided to surround the periphery of the second photoelectric conversion section 22. For example, five through-electrodes 40 may be arranged per pixel, or five or more through-electrodes 40 may be arranged per pixel.

### 2-2. Modification Example 2

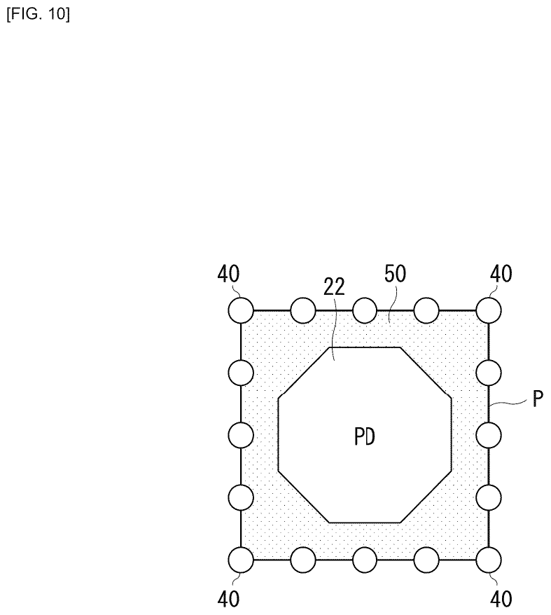

In the foregoing embodiment, the description has been given of the configuration example of the insulating section 50 having the wall surface W1. The shape of the opening 55 defined by the wall surface W1 of the insulating section 50 is not limited to the above-described example. The shape of the opening 55 is appropriately changeable, and may be a polygon, for example. FIG. 10 is a diagram illustrating an example of a planar configuration of the pixel of the imaging device 1 according to Modification Example 2. As in the example illustrated in FIG. 10, the shape of the opening 55 may be an octagon.

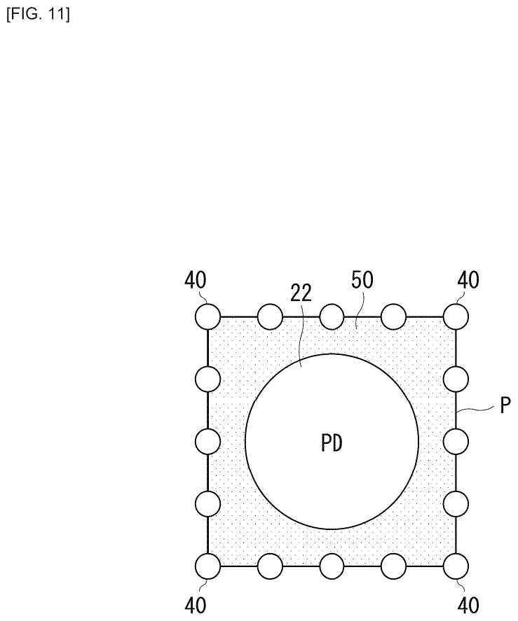

FIG. 11 is a diagram illustrating another example of the planar configuration of the pixel of the imaging device 1 according to Modification Example 2. As illustrated in FIG. 11, the shape of the opening 55 may be a circle. Forming the opening 55 to have a shape close to a circle makes it possible to reduce a difference in distances from respective positions in the second photoelectric conversion section 22 to the center of the pixel, and thus to further improve the charge transfer characteristics.

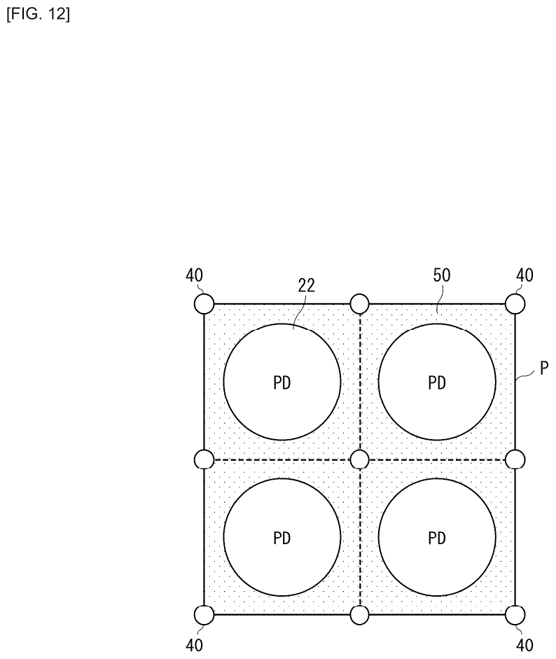

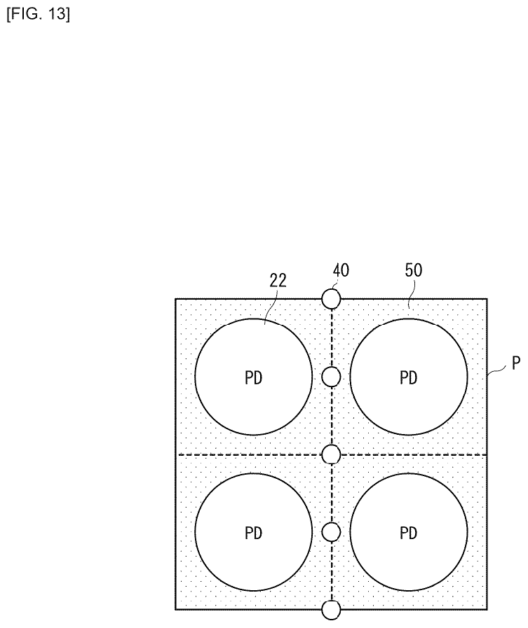

In the imaging device 1 according to the present modification example, as illustrated in FIG. 12, the through-electrodes 40 may be arranged only at four corners of the pixel P. In the example illustrated in FIG. 12, one through-electrode 40 is disposed per pixel. It is to be noted that, as in the example illustrated in FIG. 13, the through-electrodes 40 may be arranged as a whole on one side of each of the pixels P adjacent to each other. Also in the case of the example illustrated in FIG. 13, one through-electrode 40 is disposed per pixel.

### 2-3. Modification Example 3

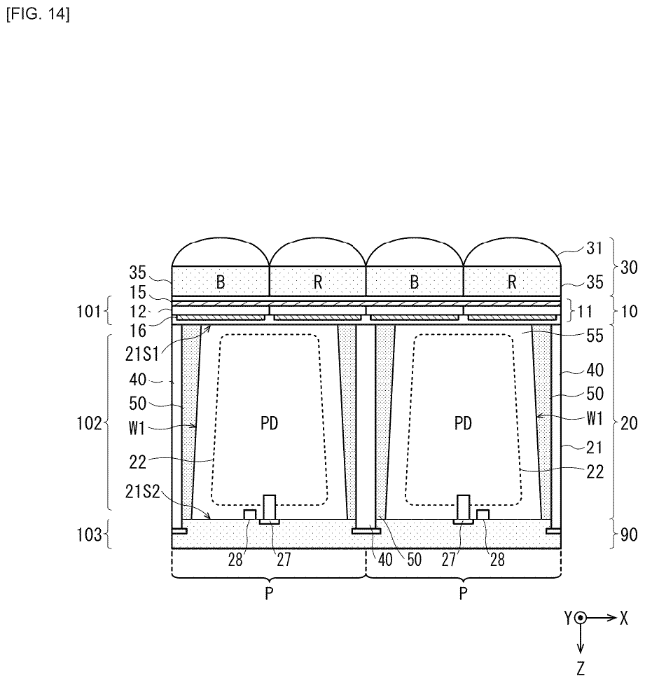

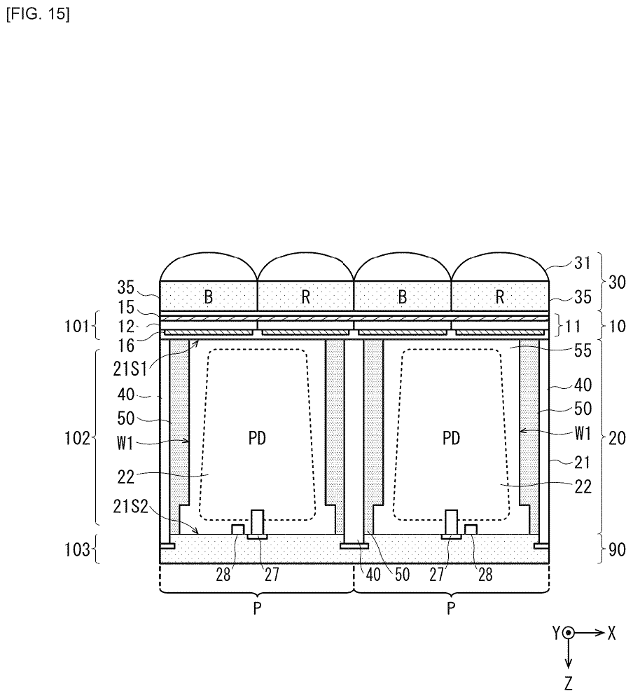

FIG. 14 is a diagram illustrating an example of a cross-sectional configuration of pixels of the imaging device 1 according to Modification Example 3. FIG. 15 is a diagram illustrating another example of the cross-sectional configuration of the pixels of the imaging device 1 according to Modification Example 3. As in the examples illustrated in FIGS. 14 and 15, the insulating section 50 may be formed to have widths different from each other at the upper part and the lower part of the insulating section 50. In a direction orthogonal to the stacking direction of the first tier 101 and the second tier 102, the width of the opening 55 defined by the wall surface W1 of the insulating section 50 is larger on a side of the third tier 103 than a side of the first tier 101.

In the example illustrated in FIG. 14, the width of the opening 55 becomes larger as being closer to the third tier 103. The wall surface W1 of the insulating section 50 is tapered, and can also be said to be an inclined surface. It can also be said, in FIG. 15, that the insulating section 50 has the wall surface W1 in a stepped shape. An area of the lower part of the opening 55 is larger than an area of the upper part of the opening 55. In such a manner, it is possible to avoid an increase in the time for charge transfer from a portion of the second photoelectric conversion section 22 near the upper part of the insulating section 50 distant from the gate electrode 27 of the transfer transistor. In addition, it is possible to sufficiently secure a region where a transistor or the like is disposed on the side of the second surface 21S2 of the semiconductor substrate 21. As schematically illustrated in FIGS. 14 and 15, it is possible to increase the volume of the second photoelectric conversion section 22 and thus to improve quantum efficiency (QE). In the present modification example, it is thus possible to ensure layout efficiency and quantum efficiency.

### 2-4. Modification Example 4

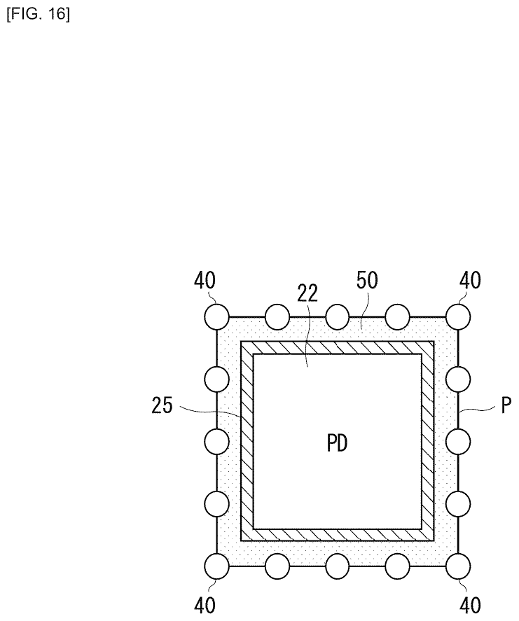

FIG. 16 is a diagram illustrating an example of a planar configuration of a pixel of the imaging device 1 according to Modification Example 4. The imaging device 1 includes a fixed charge film 25 between the second photoelectric conversion section 22 and the insulating section 50. For example, the fixed charge film 25 is formed to include at least one of oxides including hafnium (Hf), zirconium (Zr), aluminum (Al), tantalum (Ta), titanium (Ti), magnesium (Mg), yttrium (Y), and lanthanoid (La) elements. It is to be noted that the fixed charge film 25 may be configured using praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, an aluminum oxynitride film, or the like.

In the example illustrated in FIG. 16, the fixed charge film 25 is provided to surround the periphery of the second photoelectric conversion section 22. In the imaging device 1, for example, the fixed charge film 25 having negative fixed electric charge is disposed, thus making it possible to suppress generation of a dark current in the semiconductor substrate 21. It is to be noted that a film having positive fixed electric charge may be provided as the fixed charge film 25.

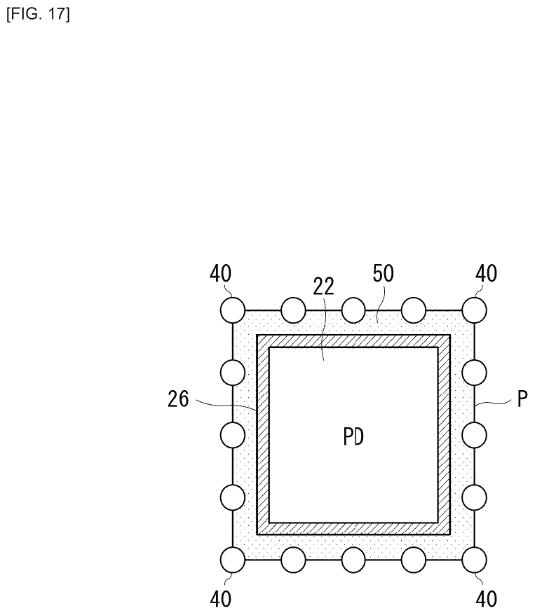

FIG. 17 is a diagram illustrating another example of the planar configuration of the pixel of the imaging device 1 according to Modification Example 4. The imaging device 1 may have a light-blocking film 26 between the second photoelectric conversion section 22 and the insulating section 50, as in the example illustrated in FIG. 17. The light-blocking film 26 is formed by a material that blocks light, e.g., a metal material such as aluminum (Al) or tungsten (W). In the imaging device 1, the light-blocking film 26 is provided around the second photoelectric conversion section 22, thus making it possible to suppress leakage of light to surrounding pixels. It is to be noted that the light-blocking film 26 may be configured using polysilicon (Poly-Si).

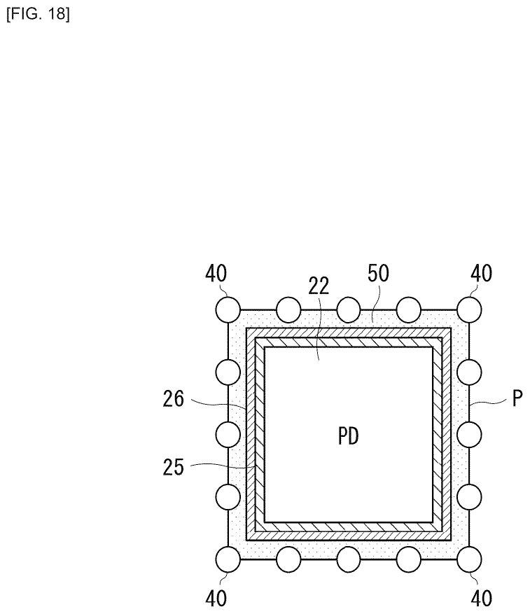

FIGS. 18 to 20 are each a diagram illustrating another example of the planar configuration of the pixel of the imaging device 1 according to Modification Example 4. As illustrated in FIG. 18, the imaging device 1 may include the fixed charge film 25 and the light-blocking film 26 between the second photoelectric conversion section 22 and the insulating section 50. The light-blocking film 26 is provided around the fixed charge film 25 between the fixed charge film 25 and the insulating section 50.

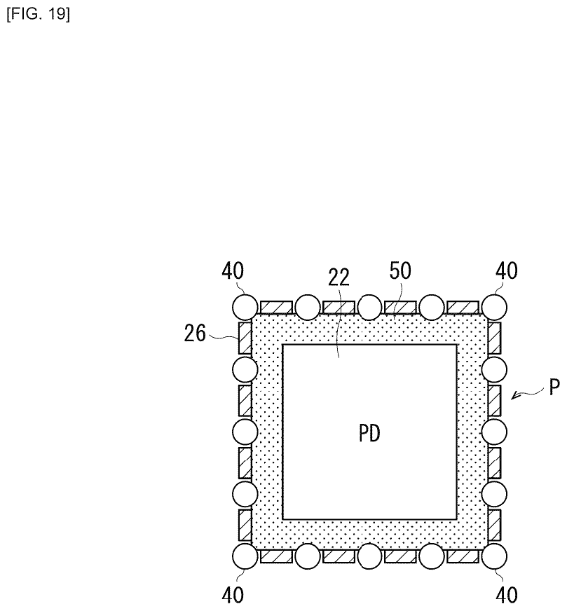

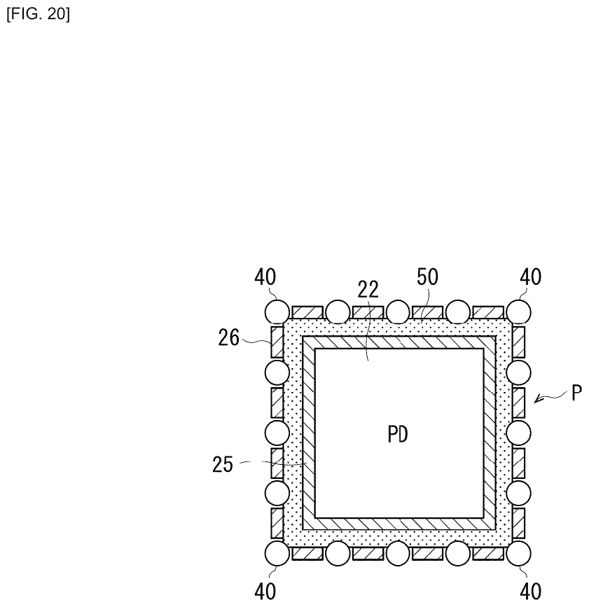

As illustrated in FIG. 19, the light-blocking film 26 may be formed at a boundary part between the pixels P adjacent to each other. In addition, as illustrated in FIG. 20, the imaging device 1 may include the fixed charge film 25 formed around the second photoelectric conversion section 22, and the light-blocking film 26 formed at the boundary between the pixels P adjacent to each other.

### 2-5. Modification Example 5

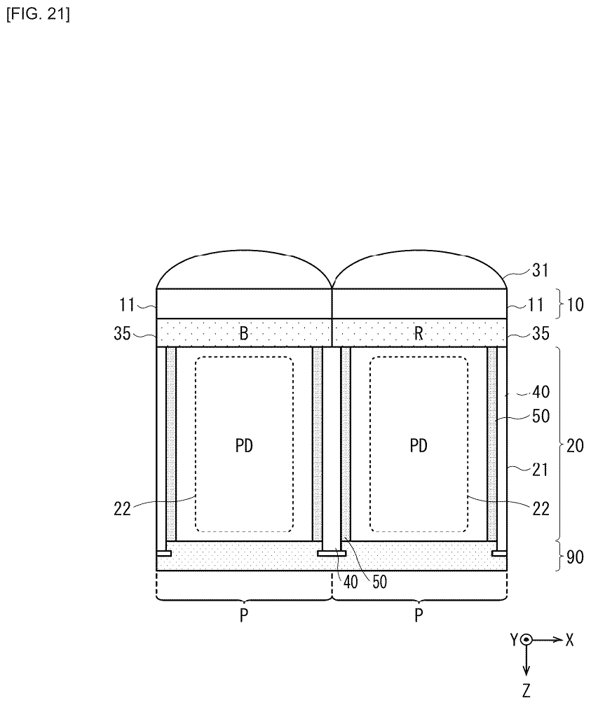

The foregoing embodiment and modification examples have described the configuration example of the pixel P, which however is merely exemplary, and the configuration of the pixel P is not limited to the above-described example. FIG. 21 is a diagram illustrating an example of a cross-sectional configuration of pixels of the imaging device 1 according to Modification Example 5. The pixel P of the imaging device 1 includes the first photoelectric conversion section 11 that selectively and photoelectrically converts light of a specific wavelength region of incident light. The color filter 35 is provided between the first photoelectric conversion section 11 and the second photoelectric conversion section 22. The second photoelectric conversion section 22 photoelectrically converts light transmitted through the first photoelectric conversion section 11 and the color filter 35.

As an example, the first photoelectric conversion section 11 photoelectrically converts light of a green wavelength region to generate electric charge. The color filter 35 of the pixel P on the left side in FIG. 21 transmits light of a blue wavelength region. The second photoelectric conversion section 22 of the pixel P on the left side photoelectrically converts incident light of the blue wavelength region to generate electric charge. Meanwhile, the color filter 35 of the pixel P on the right side transmits light of a red wavelength region. The second photoelectric conversion section 22 of the pixel P on the right side photoelectrically converts incident light of the red wavelength region to generate electric charge. The imaging device 1 generates a G pixel signal based on electric charge photoelectrically converted by the first photoelectric conversion section 11, and generates a B pixel signal and an R pixel signal based on electric charge photoelectrically converted by the second photoelectric conversion section 22. In this manner, in the present modification example, it is possible to obtain RGB pixel signals on the basis of electric charge photoelectrically converted by each of the first photoelectric conversion section 11 and the second photoelectric conversion section 22.

### 2-6. Modification Example 6

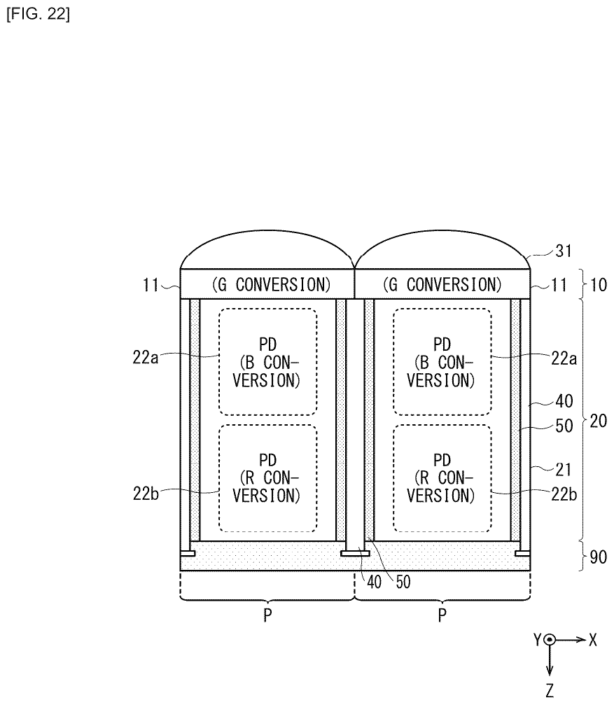

FIG. 22 is a diagram illustrating an example of a cross-sectional configuration of pixels of the imaging device 1 according to Modification Example 6. The pixel P of the imaging device 1 includes the first photoelectric conversion section 11 that selectively and photoelectrically converts light of a specific wavelength region of incident light. For example, the first photoelectric conversion section 11 photoelectrically converts light of the green wavelength region to generate electric charge. In addition, the pixel P includes second photoelectric conversion sections 22a and 22b. The second photoelectric conversion section 22a is disposed at an upper part in the semiconductor substrate 21, i.e., in a region in the semiconductor substrate 21 on the side of the first surface 21S1 to photoelectrically convert light of the blue wavelength region. The second photoelectric conversion section 22b is disposed at a lower part in the semiconductor substrate 21, i.e., in a region in the semiconductor substrate 21 on the side of the second surface 21S2 to photoelectrically convert light of the red wavelength region.

The imaging device 1 generates a G pixel signal based on electric charge photoelectrically converted by the first photoelectric conversion section 11. In addition, the imaging device 1 generates a B pixel signal based on electric charge photoelectrically converted by the second photoelectric conversion section 22a, and an R pixel signal based on electric charge photoelectrically converted by the second photoelectric conversion section 22b. In this manner, in the present modification example, it is possible to obtain RGB pixel signals on the basis of electric charge photoelectrically converted by each of the first photoelectric conversion section 11, the second photoelectric conversion section 22a, and the second photoelectric conversion section 22b.

### 2-7. Modification Example 7

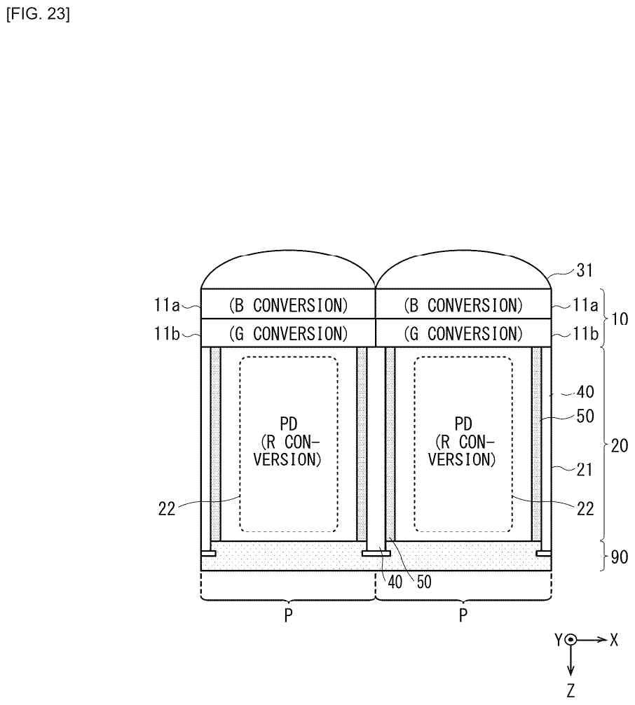

FIG. 23 is a diagram illustrating an example of a cross-sectional configuration of pixels of the imaging device 1 according to Modification Example 7. The pixel P of the imaging device 1 includes first photoelectric conversion sections 11a and 11b that each selectively and photoelectrically convert light of a specific wavelength region of incident light. The first photoelectric conversion section 11a is positioned between the lens section 31 and the first photoelectric conversion section 11b to photoelectrically convert light of the blue wavelength region, for example. The first photoelectric conversion section 11b is positioned below the first photoelectric conversion section 11a to receive light transmitted through the first photoelectric conversion section 11a. The first photoelectric conversion section 11b photoelectrically converts light of the green wavelength region, for example. In addition, the pixel P includes the second photoelectric conversion section 22. The second photoelectric conversion section 22 photoelectrically converts light transmitted through the first photoelectric conversion sections 11a and 11b, e.g., light of the red wavelength region.

The imaging device 1 generates a B pixel signal based on electric charge photoelectrically converted by the first photoelectric conversion section 11a, and a G pixel signal based on electric charge photoelectrically converted by the first photoelectric conversion section 11b. In addition, the imaging device 1 generates an R pixel signal based on electric charge photoelectrically converted by the second photoelectric conversion section 22. In this manner, in the present modification example, it is possible to obtain RGB pixel signals on the basis of electric charge photoelectrically converted by each of the first photoelectric conversion section 11a, the first photoelectric conversion section 11b, and the second photoelectric conversion section 22.

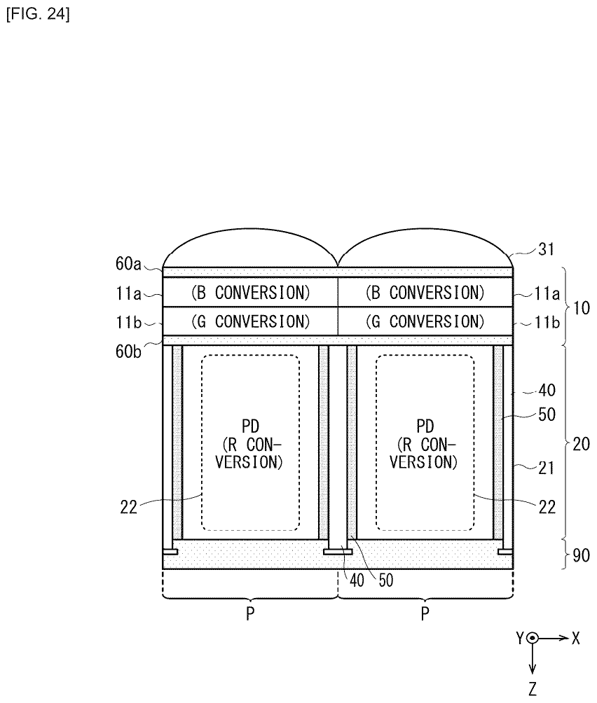

FIG. 24 is a diagram illustrating another example of the cross-sectional configuration of the pixels of the imaging device 1 according to Modification Example 7. As illustrated in FIG. 24, wiring layers 60a and 60b each including a wiring line and an interlayer insulating film may be provided. For example, the wiring layer 60a includes a wiring line coupled to an electrode of the first photoelectric conversion section 11a. The wiring layer 60b includes a wiring line coupled to an electrode of the first photoelectric conversion section 11b.

### 2-8. Modification Example 8

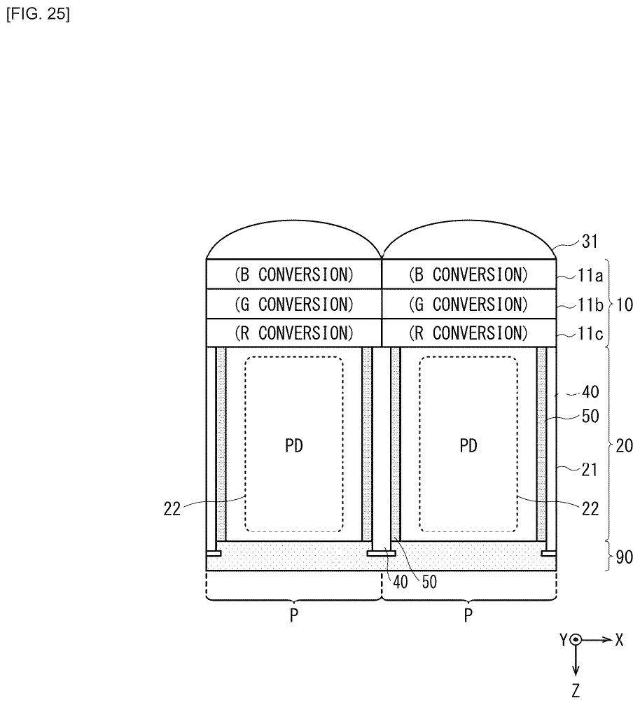

FIG. 25 is a diagram illustrating an example of a cross-sectional configuration of pixels of the imaging device 1 according to Modification Example 8. The pixel P of the imaging device 1 includes first photoelectric conversion sections 11a, 11b, and 11c that each selectively and photoelectrically convert light of a specific wavelength region of incident light. The first photoelectric conversion section 11a is positioned between the lens section 31 and the first photoelectric conversion section 11b to photoelectrically convert light of the blue wavelength region, for example. The first photoelectric conversion section 11b is positioned between the first photoelectric conversion section 11a and the first photoelectric conversion section 11c to receive light transmitted through the first photoelectric conversion section 11a. The first photoelectric conversion section 11b photoelectrically converts light of the green wavelength region, for example. The first photoelectric conversion section 11c is positioned below the first photoelectric conversion section 11b to receive light transmitted through the first photoelectric conversion section 11a and the first photoelectric conversion section 11b. The first photoelectric conversion section 11c photoelectrically converts light of the red wavelength region, for example. The imaging device 1 according to the present modification example is able to obtain RGB pixel signals on the basis of electric charge generated by each of the first photoelectric conversion sections 11a, 11b, and 11c.

In addition, the pixel P includes the second photoelectric conversion section 22. The second photoelectric conversion section 22 receives light transmitted through the first photoelectric conversion sections 11a, 11b, and 11c to generate electric charge by photoelectric conversion. For example, the second photoelectric conversion section 22 is able to generate electric charge by photoelectrically converting infrared light. The second photoelectric conversion section 22 may be utilized to generate an infrared image or a visible image, or may be utilized for the TOF sensor. In addition, the second photoelectric conversion section 22 may be utilized for the DVS, the SPAD sensor, or the like.

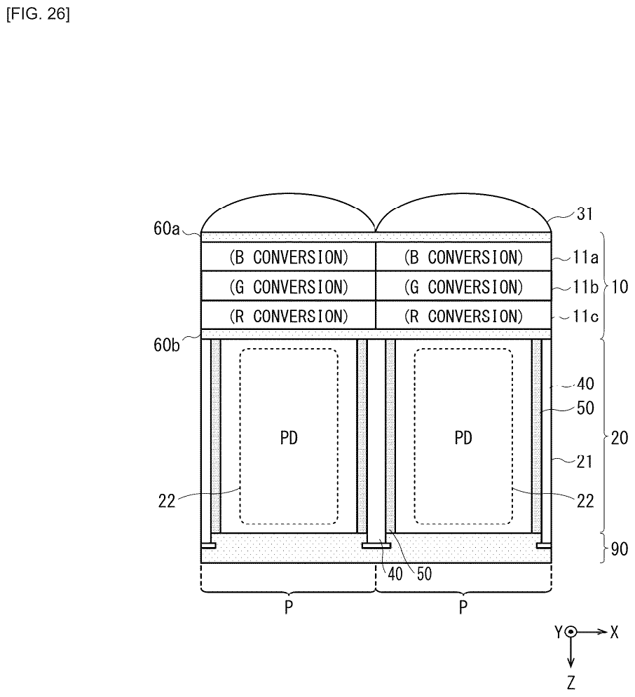

FIG. 26 is a diagram illustrating another example of the cross-sectional configuration of the pixels of the imaging device 1 according to Modification Example 8. As illustrated in FIG. 26, the wiring layers 60a and 60b each including a wiring line and an interlayer insulating film may be provided. For example, the wiring layer 60a includes a wiring line coupled to the electrode of the first photoelectric conversion section 11a. The wiring layer 60b includes a wiring line coupled to an electrode of the first photoelectric conversion section 11c.

### 2-9. Modification Example 9

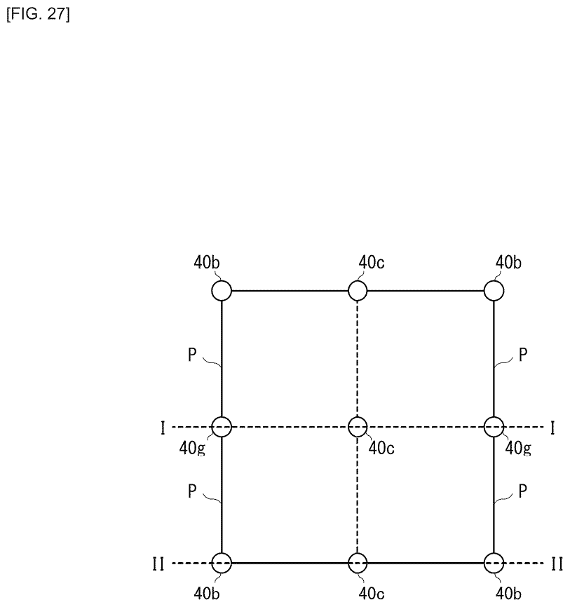

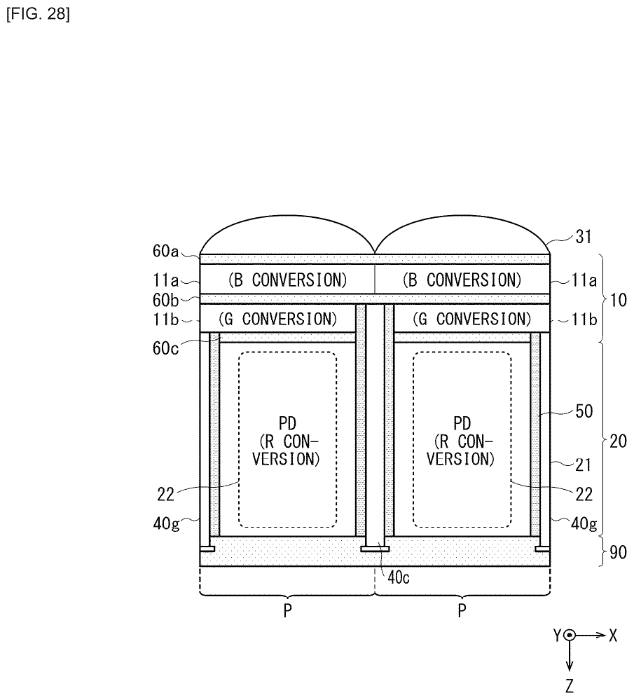

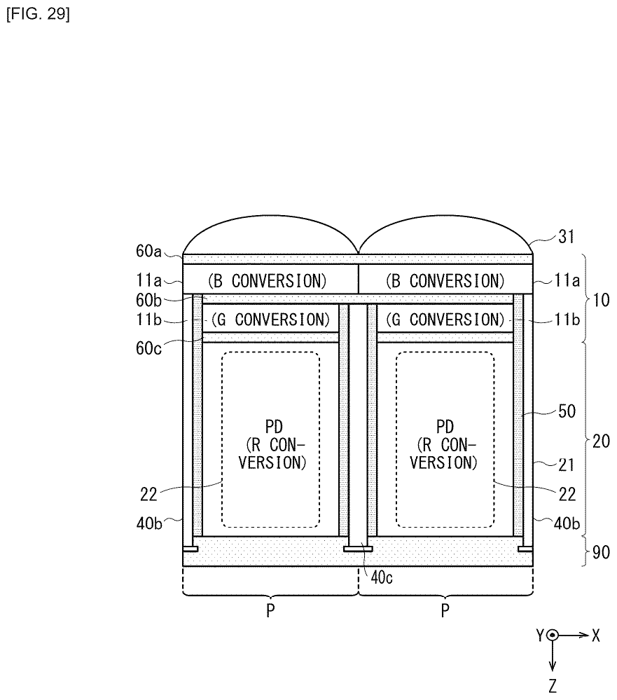

FIG. 27 is a diagram illustrating an example of a planar configuration of pixels of the imaging device 1 according to Modification Example 9. FIG. 28 illustrates an example of a cross-sectional configuration along a direction of a line I-I illustrated in FIG. 27. FIG. 29 illustrates an example of a cross-sectional configuration along a direction of a line II-II illustrated in FIG. 27. The imaging device 1 according to the present modification example includes through-electrodes 40g and 40b that transfer electric charge converted by the first photoelectric conversion section 11 and a through-electrode 40c that transmits a signal to control the first photoelectric conversion section 11.

The imaging device 1 includes the first photoelectric conversion sections 11a and 11b and the second photoelectric conversion section 22. For example, the first photoelectric conversion section 11a photoelectrically converts light of the blue wavelength region. The first photoelectric conversion section 11b photoelectrically converts light of the green wavelength region. In addition, the second photoelectric conversion section 22 photoelectrically converts light of the red wavelength region. It is to be noted that the imaging device 1 includes wiring layers 60a, 60b, and 60c each including a wiring line and an interlayer insulating film.

As illustrated in FIG. 28, the through-electrode 40c is formed to pass between the first photoelectric conversion sections 11b adjacent to each other to reach the wiring layer 60b. The through-electrode 40c is electrically coupled to at least one of the respective electrodes (e.g., the first electrode 15 described above) of the first photoelectric conversion sections 11a and 11b via the wiring line of the wiring layer 60b. It becomes possible for the vertical drive circuit 111 of the imaging device 1 to supply a voltage to drive the first photoelectric conversion sections 11a and 11b via the through-electrode 40c.

The through-electrode 40g is formed to reach the first photoelectric conversion section 11b. The through-electrode 40g is electrically coupled to the electrode (e.g., the second electrode 16 described above) of the first photoelectric conversion section 11b. It is therefore possible to transfer electric charge photoelectrically converted by the first photoelectric conversion section 11b to the above-described FD of the first readout circuit via the through-electrode 40g. This makes it possible to generate a G pixel signal based on electric charge generated by the first photoelectric conversion section 11b.

In addition, as illustrated in FIG. 29, the through-electrode 40b is formed to reach the first photoelectric conversion section 11a. The through-electrode 40b is electrically coupled to the electrode of the first photoelectric conversion section 11a, e.g., the second electrode 16. It is therefore possible to transfer electric charge photoelectrically converted by the first photoelectric conversion section 11a to the FD of the first readout circuit via the through-electrode 40b. This makes it possible to generate a B pixel signal based on electric charge generated by the first photoelectric conversion section 11a. In addition, it may be possible for the imaging device 1 to generate an R pixel signal based on electric charge generated by the second photoelectric conversion section 22. In this manner, it is possible for the imaging device 1 according to the present modification example to obtain RGB pixel signals.

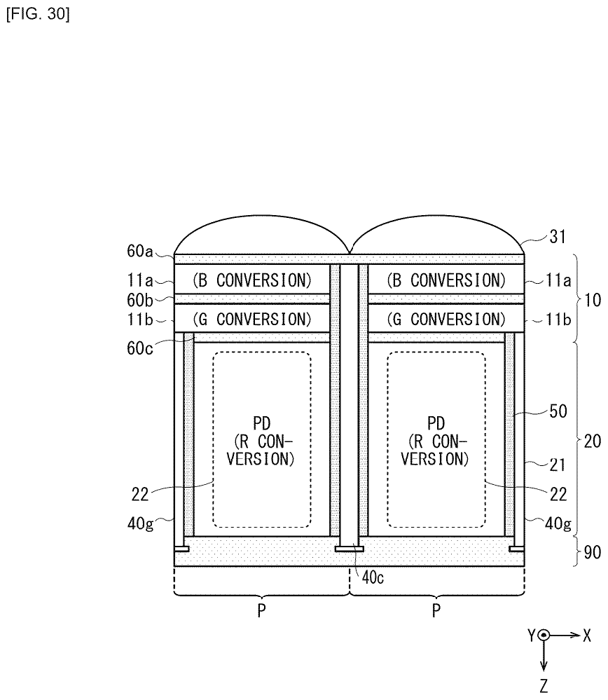

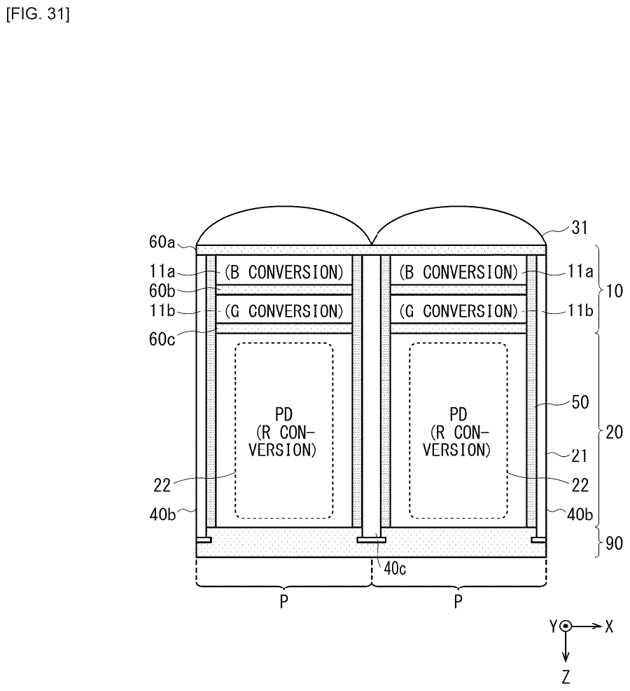

FIG. 30 illustrates another example of the cross-sectional configuration along the direction of the line I-I illustrated in FIG. 27. FIG. 31 illustrates another example of the cross-sectional configuration along the direction of the line II-II illustrated in FIG. 27. As illustrated in FIG. 30, the through-electrode 40c may be formed to pass between the first photoelectric conversion sections 11b adjacent to each other and between the first photoelectric conversion sections 11a adjacent to each other to reach the wiring layer 60a. In addition, as illustrated in FIG. 31, the through-electrode 40b may be formed to reach the wiring layer 60a.

### 2-10. Modification Example 10

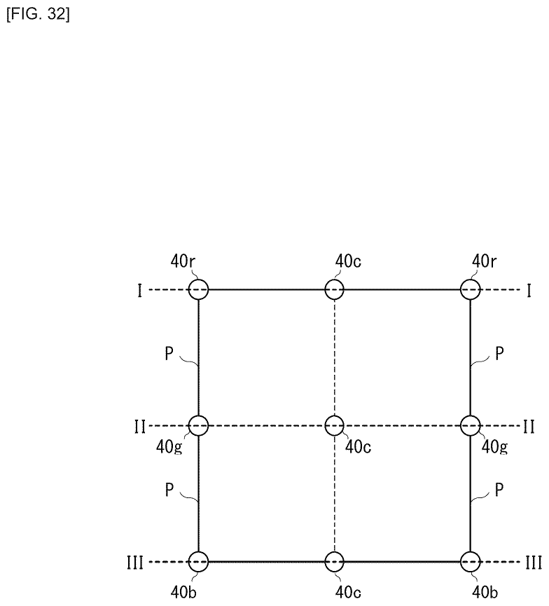

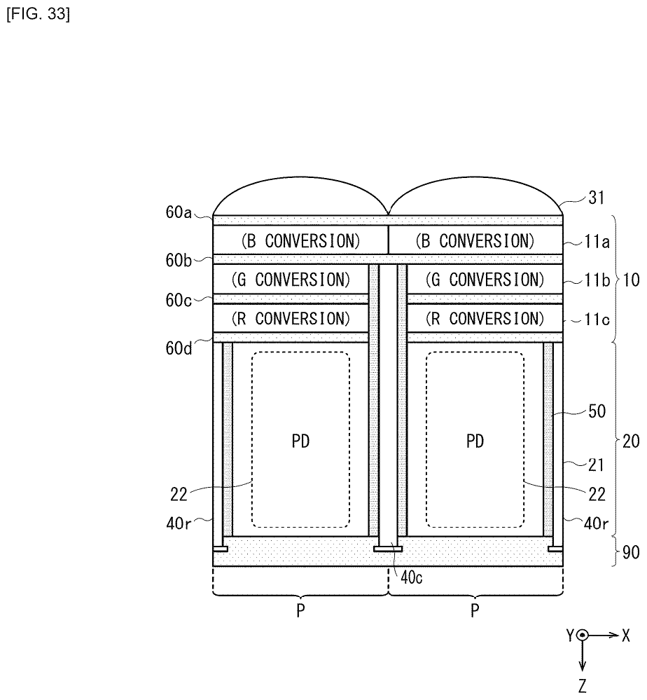

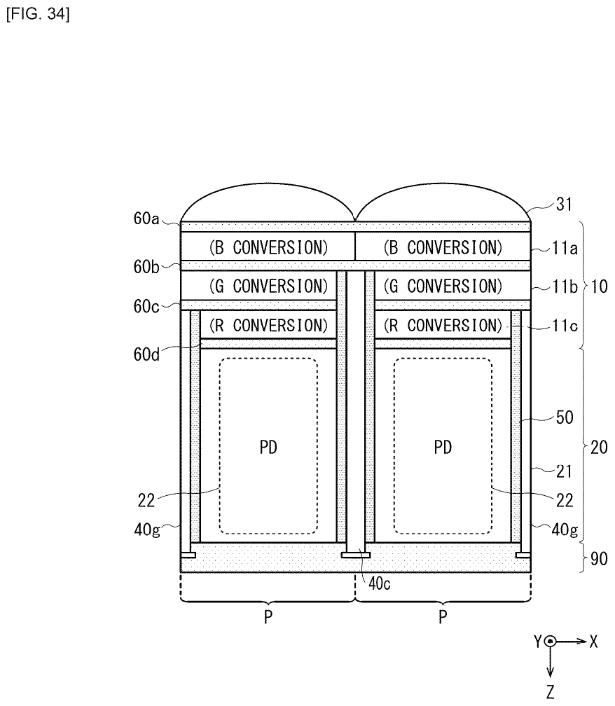

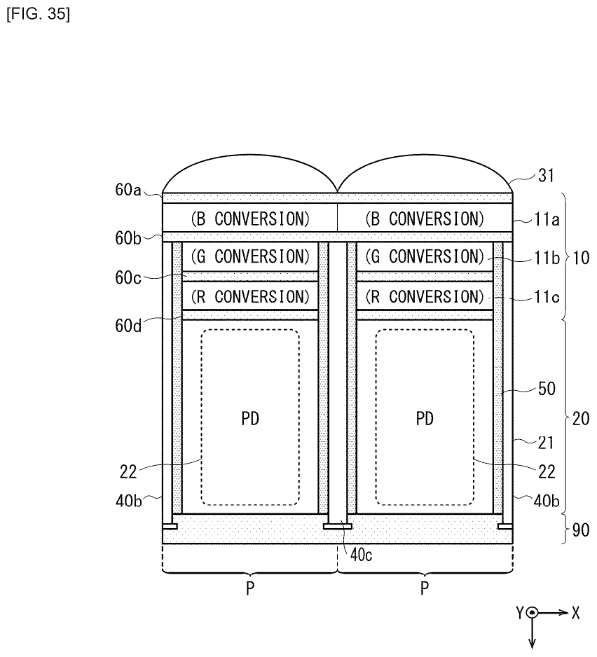

FIG. 32 is a diagram illustrating an example of a planar configuration of pixels of the imaging device 1 according to Modification Example 10. FIG. 33 illustrates an example of a cross-sectional configuration along a direction of a line I-I illustrated in FIG. 32. FIG. 34 illustrates an example of a cross-sectional configuration along a direction of a line II-II illustrated in FIG. 32. FIG. 35 illustrates an example of a cross-sectional configuration along a direction of a line III-III illustrated in FIG. 32. The imaging device 1 according to the present modification example includes through-electrodes 40r, 40g, and 40b that each transfer electric charge converted by the first photoelectric conversion section 11 and the through-electrode 40c that transfers a signal to control the first photoelectric conversion section 11.

The imaging device 1 includes the first photoelectric conversion sections 11a, 11b, and 11c, and the second photoelectric conversion section 22. For example, the first photoelectric conversion section 11a photoelectrically converts light of the blue wavelength region. The first photoelectric conversion section 11b photoelectrically converts light of the green wavelength region. The first photoelectric conversion section 11c photoelectrically converts light of the red wavelength region. In addition, the second photoelectric conversion section 22 receives light transmitted through the first photoelectric conversion sections 11a, 11b, and 11c to generate electric charge by photoelectric conversion. It is to be noted that the imaging device 1 includes wiring layers 60a, 60b, 60c, and 60d each including a wiring line and an interlayer insulating film.

The through-electrode 40μr —is formed to reach the wiring layer 60d, as illustrated in FIG. 33. The through-electrode 40r is electrically coupled to the electrode of the first photoelectric conversion section 11c via the wiring line of the wiring layer 60d. It is therefore possible to transfer electric charge photoelectrically converted by the first photoelectric conversion section 11c to the FD via the through-electrode 40μr—, and thus to obtain an R pixel signal.

The through-electrode 40μg —is formed to reach the wiring layer 60c, as illustrated in FIG. 34. The through-electrode 40g is electrically coupled to the electrode of the first photoelectric conversion section 11b via the wiring line of the wiring layer 60c. It is therefore possible to transfer electric charge photoelectrically converted by the first photoelectric conversion section 11b to the FD via the through-electrode 40μg—, and thus to obtain a G pixel signal.

In addition, the through-electrode 40μb —is formed to reach the wiring layer 60b, as illustrated in FIG. 35. The through-electrode 40b is electrically coupled to the electrode of the first photoelectric conversion section 11a via the wiring line of the wiring layer 60b. It is therefore possible to transfer electric charge photoelectrically converted by the first photoelectric conversion section 11 a to the FD via the through-electrode 40b, and thus to obtain a B pixel signal.

### 3. Application Example

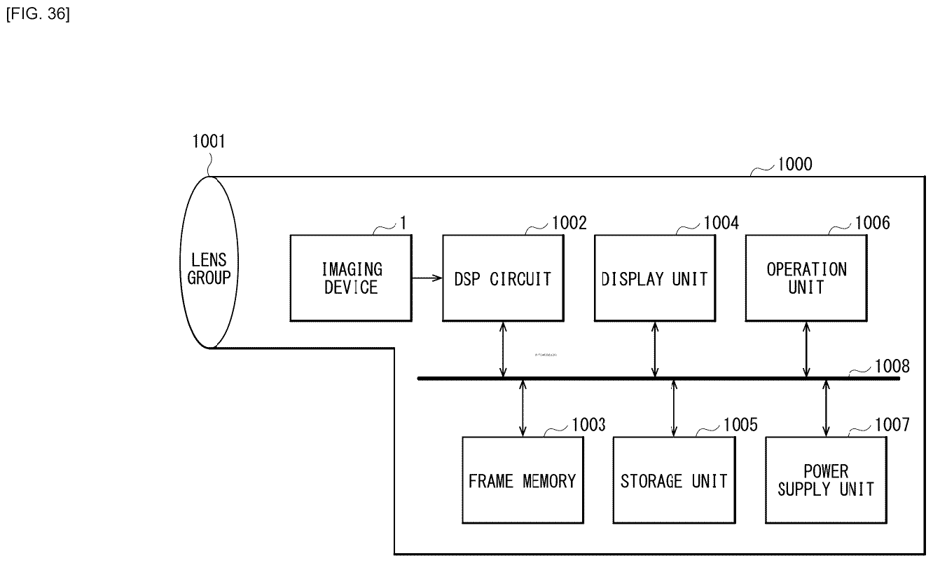

The above-described imaging device 1 or the like is applicable, for example, to any type of electronic apparatus with an imaging function including a camera system such as a digital still camera or a video camera, a mobile phone having an imaging function, and the like. FIG. 36 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject, and forms an image on an imaging surface of the imaging device 1. The imaging device 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic EL (Electro Luminescence) panel, and records image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### Example of Practical Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

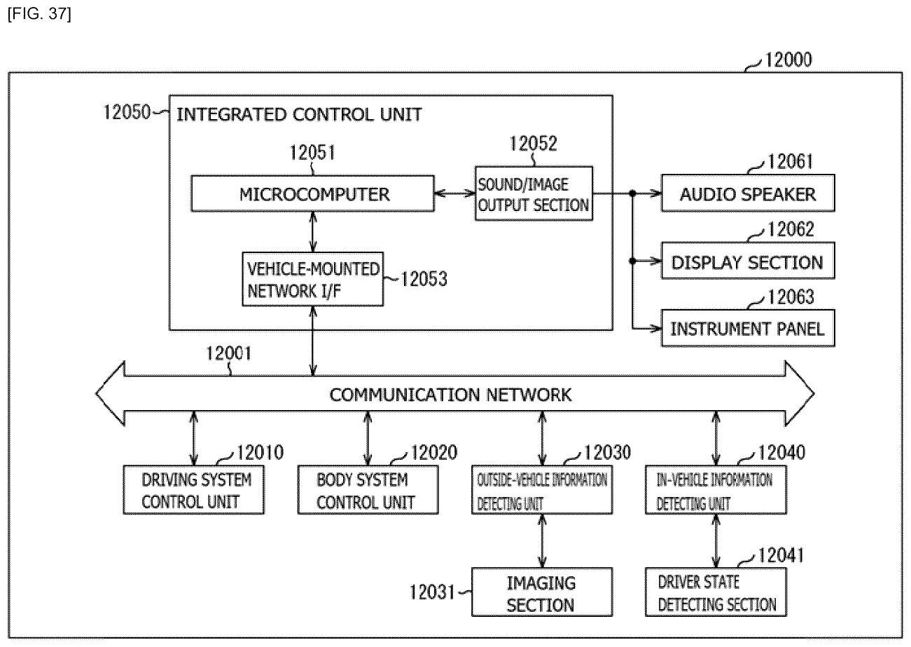

FIG. 37 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 37, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 37, an audio speaker 12061, a display section 12062, and an instrument panel 12063 are illustrated as the output device. The display section 12062 may, for example, include at least one of an on-board display and a head-up display.

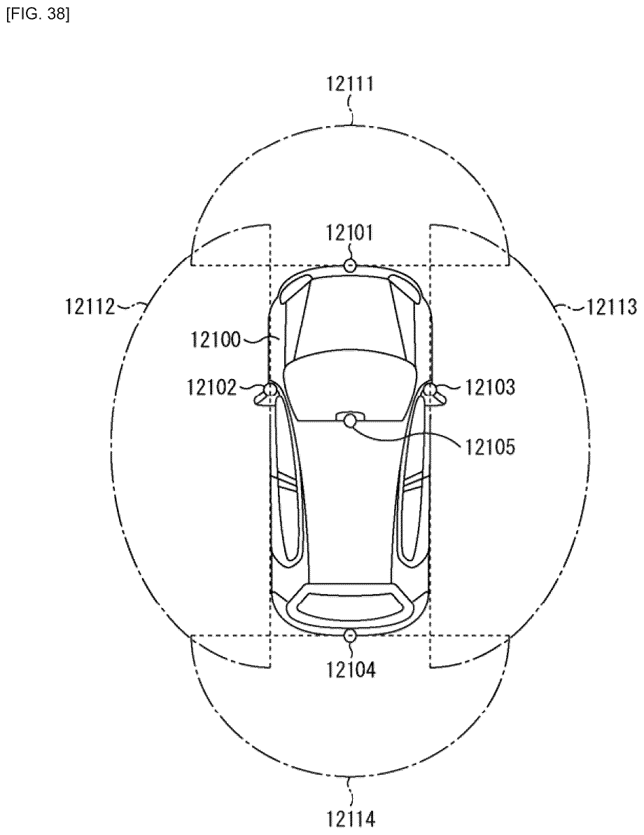

FIG. 38 is a diagram depicting an example of the installation position of the imaging section 12031.

In FIG. 38, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 38 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 can be applied to the imaging section 12031. Applying the technology according to an embodiment of the present disclosure to the imaging section 12031 enables obtainment of a photographed image having less noise and high definition, thus making it possible to perform highly accurate control utilizing the photographed image in the mobile body control system.

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

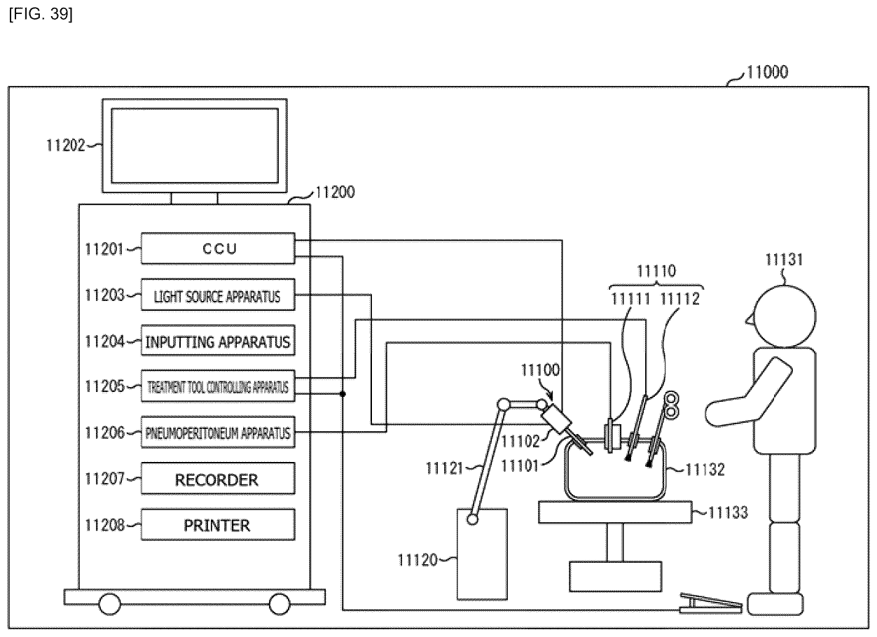

FIG. 39 is a view depicting an example of a schematic configuration of an endoscopic surgery system to which the technology according to an embodiment of the present disclosure (present technology) can be applied.

In FIG. 39, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

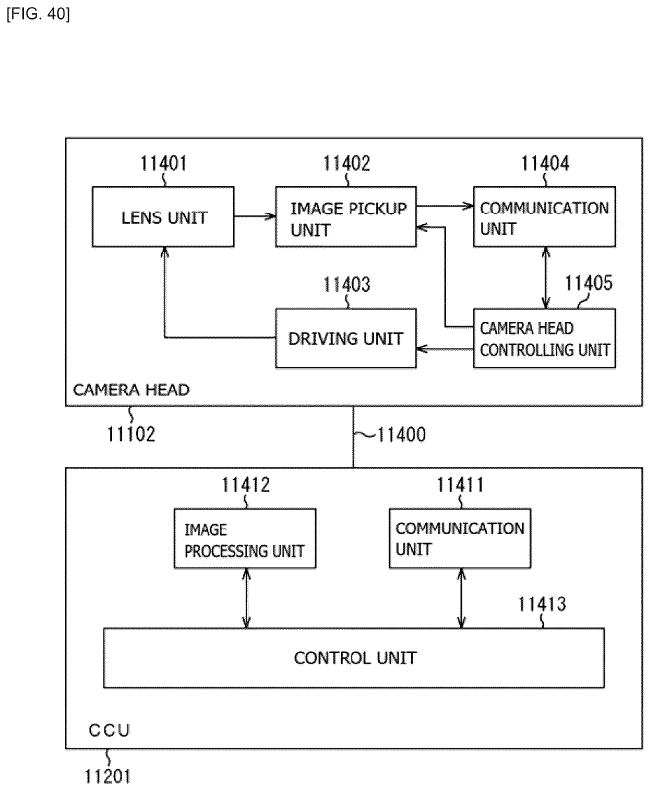

FIG. 40 is a block diagram depicting an example of a functional configuration of the camera head 11102 and the CCU 11201 depicted in FIG. 39.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 enables the image pickup unit 11402 to have high sensitivity, thus making it possible to provide the endoscope 11100 having high definition.

Although the description has been given hereinabove of the present disclosure with reference to the embodiment, the modification examples, the application example, and the practical application examples, the present technology is not limited to the foregoing embodiment and the like, and may be modified in a wide variety of ways. For example, although the foregoing modification examples have been described as modification examples of the foregoing embodiment, the configurations of the respective modification examples may be combined as appropriate. For example, the present disclosure is not limited to a back side illumination image sensor, but is also applicable to a front side illumination image sensor.

In addition, the photoelectric conversion device of the present disclosure may be in the form of a module in which an imaging section and a signal processing section or an optical system are packaged as a whole.

Further, the description has been given, in the foregoing embodiment and the like, by exemplifying the imaging device that converts the amount of incident light formed as an image on an imaging surface via the optical lens system into electric signals on a pixel-by-pixel basis and outputs the electric signals as pixel signals. However, the photoelectric conversion device of the present disclosure is not limited to such an imaging device. For example, it is sufficient for the photoelectric conversion device to detect and receive light from a subject, generate electric charge corresponding to a received light amount by photoelectric conversion, and accumulate the generated electric charge. A signal to be outputted may be a signal of image information or a signal of distance measurement information.

In addition, the description has been given, in the foregoing embodiment, by exemplifying the case where the second photoelectric conversion section 22 is the TOF sensor, but the present disclosure is not limited thereto. That is, the second photoelectric conversion section 22 is not limited to the one that detects light having a wavelength of an infrared light region, and may be the one that detects wavelength light of another wavelength region. For example, as described above as the modification example, the second photoelectric conversion section 22 may receive light of a visible light region to perform photoelectric conversion.

In addition, in the foregoing embodiment and the like, a structure may be adopted in which, for example, two organic photoelectric conversion regions or two or more organic photoelectric conversion regions are stacked. Alternatively, a structure may be adopted in which two inorganic photoelectric conversion regions or two or more inorganic photoelectric conversion regions are stacked. In addition, in the foregoing embodiment and the like, the first light-receiving unit 10 mainly detects wavelength light of a visible light region to perform photoelectric conversion, and the second light-receiving unit 20 mainly detects wavelength light of an infrared light region to perform photoelectric conversion. However, the photoelectric conversion device of the present disclosure is not limited thereto. In the photoelectric conversion device of the present disclosure, a wavelength region indicating sensitivity in each of the first photoelectric conversion section 11 and the second photoelectric conversion section 22 may be set optionally.

In addition, a constituent material of each component of the photoelectric conversion element of the present disclosure is not limited to the materials mentioned in the foregoing embodiments, and the like. For example, in a case where the first photoelectric conversion section 11 or the second photoelectric conversion section 22 receives light of a visible light region to perform photoelectric conversion, the first photoelectric conversion section 11 or the second photoelectric conversion section 22 may include quantum dots.

It is to be noted that the effects described herein are merely exemplary and are not limited to the description, and may further include other effects. In addition, the present disclosure may also have the following configurations.
(1)

A photoelectric conversion device including:
a first tier including a first first photoelectric conversion section that converts incident light into electric charge;
a second tier provided to overlap with the first tier in a first direction and including a first second photoelectric conversion section and a first insulating section, the first second photoelectric conversion section converting light transmitted through the first first photoelectric conversion section into electric charge, the first insulating section including a first wall surface that surrounds the first second photoelectric conversion section along a plane orthogonal to the first direction; and
a plurality of first through-electrodes each coupled to the first first photoelectric conversion section and penetrating the second tier in a region outside the first wall surface.
(2)

The photoelectric conversion device according to (1), in which the first wall surface has a planar shape.
(3)

The photoelectric conversion device according to (1) or (2), in which the first wall surface has an octagonal shape in the plane orthogonal to the first direction.
(4)

The photoelectric conversion device according to (1) or (2), in which the first wall surface has a circular shape in the plane orthogonal to the first direction.
(5)

The photoelectric conversion device according to any one of (1) to (4), in which the plurality of first through-electrodes is provided in the plane orthogonal to the first direction.
(6)

The photoelectric conversion device according to any one of (1) to (5), in which the plurality of first through-electrodes includes a through-electrode that transfers electric charge converted by the first photoelectric conversion section, and a through-electrode that transmits a signal to control the first photoelectric conversion section.
(7)

The photoelectric conversion device according to any one of (1) to (6), further including a plurality of second through-electrodes, in which
the first tier further includes a second first photoelectric conversion section provided next to the first first photoelectric conversion section and converting incident light into electric charge,
the second tier further includes a second second photoelectric conversion section and a second insulating section, the second second photoelectric conversion section being provided next to the first second photoelectric conversion section and converting light transmitted through the second first photoelectric conversion section into electric charge, the second insulating section including a second wall surface surrounding the second second photoelectric conversion section along the plane orthogonal to the first direction, and
the plurality of second through-electrodes is each coupled to the second first photoelectric conversion section, and penetrates the second tier in a region outside the second wall surface.
(8)

The photoelectric conversion device according to (7), in which
the first through-electrode is provided between the first second photoelectric conversion section and the second second photoelectric conversion section, and
an interval between a first opening defined by the first wall surface and a second opening defined by the second wall surface is greater than an interval between the first opening and the first through-electrode.
(9)

The photoelectric conversion device according to any one of (1) to (8), further including a third tier including a wiring line coupled to the first through-electrode, in which
the second tier further includes a transfer section that transfers electric charge converted by the first photoelectric conversion section on a side of the third tier.
(10)

The photoelectric conversion device according to (9), in which a width of the first opening defined by the first wall surface is larger on the side of the third tier than on a side of the first tier, in a direction orthogonal to the first direction.
(11)

The photoelectric conversion device according to (9) or (10), in which the width of the first opening defined by the first wall surface becomes larger as being closer to the third tier, in the direction orthogonal to the first direction.
(12)

The photoelectric conversion device according to any one of (1) to (11), in which the second photoelectric conversion section is configured to acquire distance information on an object.
(13)

A photoelectric conversion device including:
a first tier including a first first photoelectric conversion section that converts incident light into electric charge;
a second tier provided to overlap with the first tier in a first direction and including a first second photoelectric conversion section and a first insulating section, the first second photoelectric conversion section converting light transmitted through the first first photoelectric conversion section into electric charge, the first insulating section including a first wall surface that surrounds the first second photoelectric conversion section along a plane orthogonal to the first direction; and
a plurality of first through-electrodes each coupled to the first first photoelectric conversion section and penetrating the second tier in a region outside the first wall surface, in which
the first wall surface has a circular shape in the plane orthogonal to the first direction.
(14)

The photoelectric conversion device according to any one of (1) to (13), in which the photoelectric conversion device includes an imaging device.

The present application claims the benefit of Japanese Priority Patent Application JP2021-181455 filed with the Japan Patent Office on Nov. 5, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion device comprising:
a first tier including a first first photoelectric conversion section that converts incident light into electric charge;
a second tier provided to overlap with the first tier in a first direction and including a first second photoelectric conversion section and a first insulating section, the first second photoelectric conversion section converting light transmitted through the first first photoelectric conversion section into electric charge, the first insulating section including a first wall surface that surrounds the first second photoelectric conversion section along a plane orthogonal to the first direction; and
a plurality of first through-electrodes each coupled to the first first photoelectric conversion section and penetrating the second tier in a region outside the first wall surface.

2. The photoelectric conversion device according to claim 1, wherein the first wall surface has a planar shape.

3. The photoelectric conversion device according to claim 1, wherein the first wall surface has an octagonal shape in the plane orthogonal to the first direction.

4. The photoelectric conversion device according to claim 1, wherein the first wall surface has a circular shape in the plane orthogonal to the first direction.

5. The photoelectric conversion device according to claim 1, wherein the plurality of first through-electrodes is provided in the plane orthogonal to the first direction.

6. The photoelectric conversion device according to claim 1, wherein the plurality of first through-electrodes includes a through-electrode that transfers electric charge converted by the first photoelectric conversion section, and a through-electrode that transmits a signal to control the first photoelectric conversion section.

7. The photoelectric conversion device according to claim 1, further comprising a plurality of second through-electrodes, wherein
the first tier further includes a second first photoelectric conversion section provided next to the first first photoelectric conversion section and converting incident light into electric charge,
the second tier further includes a second second photoelectric conversion section and a second insulating section, the second second photoelectric conversion section being provided next to the first second photoelectric conversion section and converting light transmitted through the second first photoelectric conversion section into electric charge, the second insulating section including a second wall surface surrounding the second second photoelectric conversion section along the plane orthogonal to the first direction, and
the plurality of second through-electrodes is each coupled to the second first photoelectric conversion section, and penetrates the second tier in a region outside the second wall surface.

8. The photoelectric conversion device according to claim 7, wherein
the first through-electrode is provided between the first second photoelectric conversion section and the second second photoelectric conversion section, and
an interval between a first opening defined by the first wall surface and a second opening defined by the second wall surface is greater than an interval between the first opening and the first through-electrode.

9. The photoelectric conversion device according to claim 1, further comprising a third tier including a wiring line coupled to the first through-electrode, wherein
the second tier further includes a transfer section that transfers electric charge converted by the first photoelectric conversion section on a side of the third tier.

10. The photoelectric conversion device according to claim 9, wherein a width of a first opening defined by the first wall surface is larger on the side of the third tier than on a side of the first tier, in a direction orthogonal to the first direction.

11. The photoelectric conversion device according to claim 9, wherein a width of a first opening defined by the first wall surface becomes larger as being closer to the third tier, in a direction orthogonal to the first direction.

12. The photoelectric conversion device according to claim 1, wherein the second photoelectric conversion section is configured to acquire distance information on an object.

13. A photoelectric conversion device comprising:
a first tier including a first first photoelectric conversion section that converts incident light into electric charge;
a second tier provided to overlap with the first tier in a first direction and including a first second photoelectric conversion section and a first insulating section, the first second photoelectric conversion section converting light transmitted through the first first photoelectric conversion section into electric charge, the first insulating section including a first wall surface that surrounds the first second photoelectric conversion section along a plane orthogonal to the first direction; and
a plurality of first through-electrodes each coupled to the first first photoelectric conversion section and penetrating the second tier in a region outside the first wall surface, wherein
the first wall surface has a circular shape in the plane orthogonal to the first direction.

14. The photoelectric conversion device according to claim 1, wherein the photoelectric conversion device comprises an imaging device.
